(19) United States
(12) Patent Application Publication
(10) Pub. No.: US 2017/0162545 A1
(43) Pub. Date: Jun. 8, 2017

(54) STACKED SEMICONDUCTOR DEVICE AND A METHOD OF MANUFACTURING THE SAME

(71) Applicant: SAMSUNG ELECTRONICS CO., LTD., SUWON-SI (KR)

(72) Inventors: MIN-SANG PARK, YONGIN-SI (KR); KYO-MIN SOHN, YONGIN-SI (KR)

(21) Appl. No.: 15/334,667

(22) Filed: Oct. 26, 2016

(30) Foreign Application Priority Data
Dec. 7, 2015 (KR) 10-2015-0172996

(51) Int. Cl. H01L 25/065; H01L 23/367; H01L 25/00; H01L 25/18; H01L 23/00

(52) U.S. Cl. CPC H01L 25/0657; H01L 25/18; H01L 24/17; H01L 25/50; H01L 23/367; H01L 2225/06513; H01L 2225/06527; H01L 2225/06541; H01L 2225/06589; H01L 2224/17181; H01L 2224/1712; H01L 2224/17517; H01L 2224/17519

(57) ABSTRACT

A stacked semiconductor device includes a plurality of semiconductor dies and a plurality of thermal-mechanical bumps. The semiconductor dies are stacked in a vertical direction. The thermal-mechanical bumps are disposed in bump layers between the semiconductor dies. Fewer thermal-mechanical bumps are disposed at a location near a heat source included in the semiconductor dies than at other locations, or a structure of the thermal-mechanical bumps at the location near the heat source is different from a structure of the thermal-mechanical bumps at other locations.

### CROSS-REFERENCE TO RELATED APPLICATION

This U.S. Non-provisional Patent Application claims priority under 35 U.S.C. §119 to Korean Patent Application No. 10-2015-0172996, filed on Dec. 7, 2015, in the Korean Intellectual Property Office (KIPO), the disclosure of which is incorporated by reference herein in its entirety.

### 1. TECHNICAL FIELD

Exemplary embodiments of the inventive concept relate to semiconductor integrated circuits, and more particularly, to a stacked semiconductor device and a method of manufacturing the same.

### 2. DISCUSSION OF THE RELATED ART

Stacked semiconductor devices, in other words, three-dimensional semiconductor integrated circuits, have been introduced to reduce sizes of devices and/or systems. In the stacked semiconductor device, circuits are distributed and integrated in different semiconductor dies and then the semiconductor dies are stacked vertically. The stacked semiconductor device may include various types of semiconductor dies and at least one of the semiconductor dies may produce an excessive amount of heat during a normal operation. The excess heat may degrade the performance of the stacked semiconductor device.

### SUMMARY

According to an exemplary embodiment of the inventive concept, a stacked semiconductor device includes a plurality of semiconductor dies and a plurality of thermal-mechanical bumps. The semiconductor dies are stacked in a vertical direction. The thermal-mechanical bumps are disposed in bump layers between the semiconductor dies. Fewer thermal-mechanical bumps are disposed at a location near a heat source included in the semiconductor dies than at other locations, or a structure of the thermal-mechanical bumps at the location near the heat source is different from a structure of the thermal-mechanical bumps at other locations.

According to an exemplary embodiment of the inventive concept, a method of manufacturing a stacked semiconductor device includes stacking a plurality of semiconductor dies in a vertical direction, disposing a plurality of thermal-mechanical bumps in bump layers between the semiconductor dies and changing a location or a structure of the thermal-mechanical bumps in view of a location of a heat source included in the semiconductor dies.

According to an exemplary embodiment of the inventive concept, a method of manufacturing a stacked memory device includes integrating a plurality of function blocks forming a memory device in a plurality of semiconductor dies, stacking the semiconductor dies in a vertical direction, disposing a plurality of thermal-mechanical bumps in bump layers between the semiconductor dies and changing a disposition or a structure of the thermal-mechanical bumps depending on a location of a heat source included in the semiconductor dies.

According to an exemplary embodiment of the inventive concept, a semiconductor device includes: a first semiconductor die disposed on a substrate; a layer disposed on the first semiconductor die; a second semiconductor die disposed on the substrate, wherein the first semiconductor die, the layer and the second semiconductor die are sequentially arranged in a direction perpendicular to an upper surface of the substrate; a heat source disposed in the first semiconductor die; a heat vulnerable region disposed in the second semiconductor die and near the heat source; and a plurality of thermal-mechanical bumps disposed in the layer, wherein a number of the thermal-mechanical bumps near the heat source is less than that away from the heat source, or a characteristic of the thermal-mechanical bumps near the heat source is different from that of those away from the heat source.

### BRIEF DESCRIPTION OF THE DRAWINGS

The above and other features of the inventive concept will become more clearly understood by describing in detail exemplary embodiments thereof with reference to the accompanying drawings.

FIG. 1 is a flowchart illustrating a method of manufacturing a stacked semiconductor device according to an exemplary embodiment of the inventive concept.

FIG. 2 is a cross-sectional view of a stacked semiconductor device according to an exemplary embodiment of the inventive concept.

FIGS. 3 and 4 are diagrams each illustrating a disposition of bumps in the stacked semiconductor device of FIG. 2 according to an exemplary embodiment of the inventive concept.

FIG. 5 is a cross-sectional view of a stacked semiconductor device according to an exemplary embodiment of the inventive concept.

FIG. 6 is a diagram illustrating a disposition of bumps in the stacked semiconductor device of FIG. 5 according to an exemplary embodiment of the inventive concept.

FIG. 7 is a cross-sectional view of a stacked semiconductor device according to an exemplary embodiment of the inventive concept.

FIG. 8 is a diagram illustrating a disposition of bumps in the stacked semiconductor device of FIG. 7 according to an exemplary embodiment of the inventive concept.

FIG. 9 is a cross-sectional view of a stacked semiconductor device according to an exemplary embodiment of the inventive concept.

FIG. 10 is a diagram illustrating a disposition of bumps in the stacked semiconductor device of FIG. 9 according to an exemplary embodiment of the inventive concept.

FIGS. 11, 12, 13 and 14 are cross-sectional views of a stacked semiconductor device according to exemplary embodiments of the inventive concept.

FIG. 15 is a cross-sectional view illustrating a structure of a semiconductor device including a thermal-mechanical bump according to an exemplary embodiment of the inventive concept.

FIGS. 16, 17, 18, 19 and 20 are cross-sectional views illustrating stages of a method of manufacturing the semiconductor device of FIG. 15 according to an exemplary embodiment of the inventive concept.

FIG. 21 is a cross-sectional view illustrating a structure of a semiconductor device including a thermal-mechanical bump according to an exemplary embodiment of the inventive concept.

FIG. 22 is a diagram illustrating a disposition of thermal-mechanical bumps in a stacked semiconductor device according to an exemplary embodiment of the inventive concept.

FIG. 23 is a cross-sectional view illustrating a structure of the semiconductor device including the thermal-mechanical bump of FIG. 22 according to an exemplary embodiment of the inventive concept.

FIG. 24 is a diagram illustrating a disposition of thermal-mechanical bumps in a stacked semiconductor device according to an exemplary embodiment of the inventive concept.

FIG. 25 is a cross-sectional view illustrating a structure of the semiconductor device including the thermal-mechanical bump of FIG. 24 according to an exemplary embodiment of the inventive concept.

FIG. 26 is a diagram illustrating a disposition of thermal-mechanical bumps in a stacked semiconductor device according to an exemplary embodiment of the inventive concept.

FIG. 27 is a cross-sectional view illustrating a structure of the semiconductor device including the thermal-mechanical bump of FIG. 26 according to an exemplary embodiment of the inventive concept.

FIGS. 28 and 29 are block diagrams illustrating a semiconductor memory device according to an exemplary embodiment of the inventive concept.

FIG. 30 is a diagram illustrating a stacked semiconductor device according to an exemplary embodiment of the inventive concept.

FIG. 31 is a block diagram illustrating a memory module according to an exemplary embodiment of the inventive concept.

FIGS. 32 and 33 are diagrams illustrating structures of a stacked memory device according to exemplary embodiments of the inventive concept.

FIG. 34 is a block diagram illustrating a memory system according to an exemplary embodiment of the inventive concept.

FIG. 35 is a diagram for describing a package structure of a memory chip according to an exemplary embodiment of the inventive concept.

FIG. 36 is a diagram illustrating a system according to an exemplary embodiment of the inventive concept.

FIG. 37 is a block diagram illustrating a mobile system according to an exemplary embodiment of the inventive concept.

FIG. 38 is a block diagram illustrating a computing system according to an exemplary embodiment of the inventive concept.

### DETAILED DESCRIPTION OF THE EMBODIMENTS

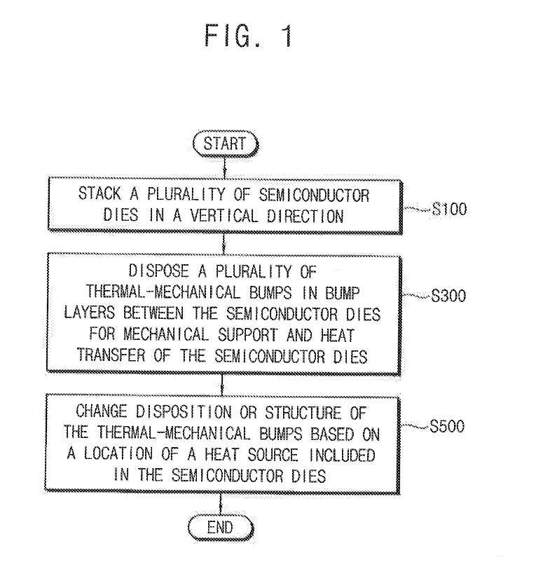

FIG. 1 is a flowchart illustrating a method of manufacturing a stacked semiconductor device according to an exemplary embodiment of the inventive concept.

Referring to FIG. 1, a plurality of semiconductor dies are stacked in a vertical direction (S100). In an exemplary embodiment of the inventive concept, the semiconductor die may represent a semiconductor substrate and structures over and/or under the semiconductor substrate. The semiconductor die itself may also be referred to as a semiconductor chip. The number of the stacked semiconductor dies may be changed variously. In an exemplary embodiment of the inventive concept, the stacked semiconductor dies may include at least two identical or homogeneous semiconductor dies. In an exemplary embodiment of the inventive concept, the stacked semiconductor dies may include at least two different or heterogeneous semiconductor dies. For example, the stacked semiconductor dies may include at least one semiconductor die in which memory cells are integrated and at least one semiconductor die in which circuits for controlling the memory cells are integrated.

A plurality of thermal-mechanical bumps are disposed in bump layers between the semiconductor dies for mechanical support and heat transfer of the semiconductor dies (S300). In an exemplary embodiment of the inventive concept, a thermal-mechanical bump may be differentiated from a signal bump. The signal bump is a bump for transferring an electrical signal or a power between the stacked semiconductor dies or between the stacked semiconductor dies and an external device. The thermal-mechanical bump is a bump for transferring heat between the stacked semiconductor dies or between the stacked semiconductor dies and an external device or for supporting the stack structure of the semiconductor dies. The thermal-mechanical bump may not be needed for the signal transfer.

If a bump performs functions of transferring a signal or a power, it is referred to as a signal bump, even if the bump also provides functions of heat transfer and/or mechanical support. The signal bump may be electrically connected to a vertical contact such as a through-silicon via or a through-substrate via (TSV). The thermal-mechanical bump may not be electrically connected to the vertical contact. Depending on the need, the thermal-mechanical bump may be connected to the vertical contact to increase heat transfer efficiency.

Based on a location of a heat source included in the semiconductor dies, a disposition or structure of the thermal-mechanical bumps is changed (S500). The disposition of the thermal-mechanical bumps may represent a number or density of the bumps, an arrangement shape of the bumps, etc. The structure of the thermal-mechanical bumps may represent a size, a material, a shape of each bump, etc. In addition, the disposition and the structure may include a bump pad formed between the bump and the surface of the semiconductor die.

In an exemplary embodiment of the inventive concept, the number or the density of the thermal-mechanical bumps may be decreased or increased to decrease or increase heat transfer from the semiconductor die including the heat source. In an exemplary embodiment of the inventive concept, the thermal conductivity of the material forming the thermal-mechanical bumps may be decreased or increased to decrease or increase heat transfer from the semiconductor die including the heat source. As a result, with respect to at least two bump layers of the bump layers, the disposition or the structure of the thermal-mechanical bumps may be different per bump layer.

The heat source represents a local portion of the semiconductor die that consumes power consistently and generates an excessive amount of heat. For example, the heat source may include a circuit using a clock signal toggling at a high frequency, a phase-locked loop, etc. If the homogeneous semiconductor dies are stacked, the heat source may not be considered and the thermal-mechanical bumps may be disposed uniformly in all of the bump layers between the stacked semiconductor dies. The overall performance of the stacked semiconductor device may be increased by dissipating the heat uniformly through the thermal-mechanical bumps. However, the overall performance of the stacked semiconductor device may be decreased by the heat transfer if a region vulnerable to heat exists near the heat source. For example, the memory device has to perform the refresh operation more frequently as the operation temperature increases because the data retention time of the memory cells decreases as the operation temperature increases. The speed of read and write operations of the memory device may then be decreased due to increase in time taken to perform the refresh operations. Consequently, excessive heat may be transferred to the memory cells through the thermal-mechanical bumps, thereby degrading the performance of the memory device.

The stacked semiconductor device and the method of manufacturing the stacked semiconductor device according to exemplary embodiments of the inventive concept may efficiently dissipate the excessive amount of heat from the heat source by changing the disposition or the structure of the thermal-mechanical bumps based on the location of the heat source. The thermal characteristics may be optimized through the dissipation of the excessive amount of heat, and thus, performance and productivity of the stacked semiconductor device may be increased.

Hereinafter, a vertical direction may be represented by Z and two horizontal directions perpendicular to each other and to the vertical direction Z may be represented by X and Y. The vertical direction Z may include an upward direction +Z and a downward direction −Z.

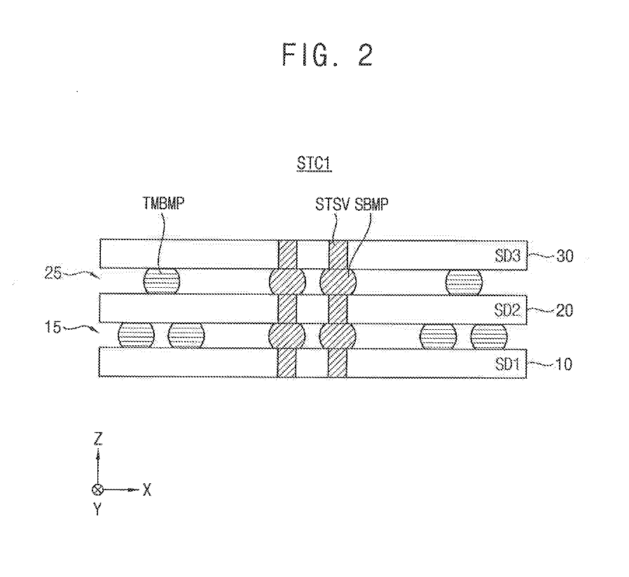

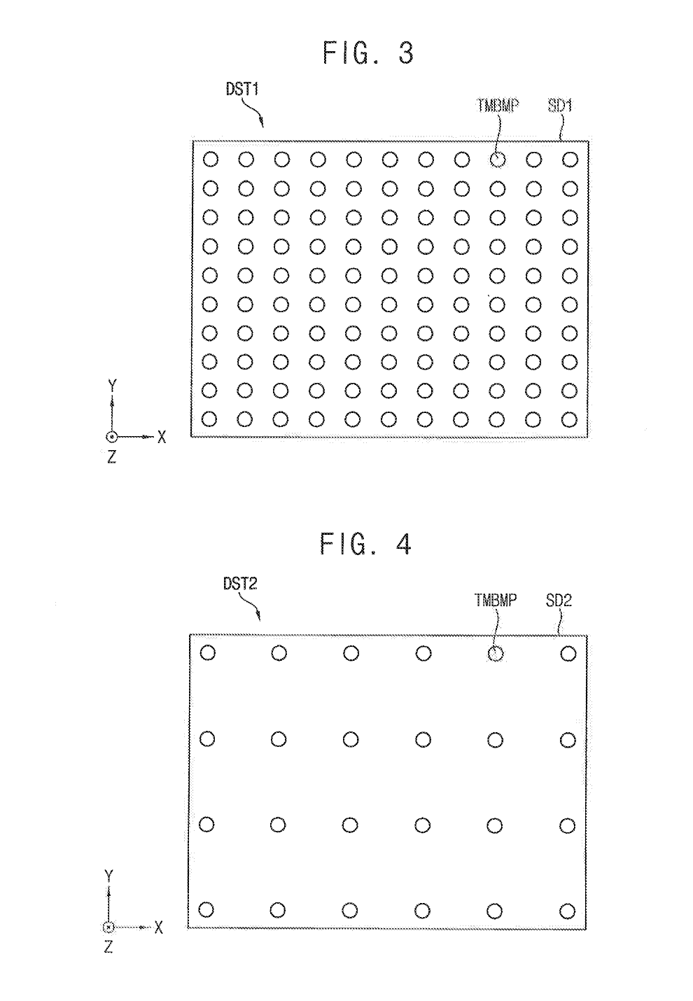

FIG. 2 is a cross-sectional view of a stacked semiconductor device according to an exemplary embodiment of the inventive concept, and FIGS. 3 and 4 are diagrams each illustrating a disposition of bumps in the stacked semiconductor device of FIG. 2 according to an exemplary embodiment of the inventive concept.

Referring to FIG. 2, a stacked semiconductor device STC1 may include first, second and third semiconductor dies SD1, SD2 and SD3 stacked in the vertical direction Z, signal bumps SBMP and thermal-mechanical bumps TMBMP. FIG. 2 illustrates three semiconductor dies 10, 20 and 30 for convenience of illustration but a larger number of the semiconductor dies may be stacked.

The signal bumps SBMP may transfer electrical signals and/or power between the semiconductor dies 10, 20 and 30. For example, the signal bumps SBMP may be electrically connected to vertical contacts such as through-substrate vias STSV.

The thermal-mechanical bumps TMBMP may be disposed in first and second bump layers 15, 25 between the semiconductor dies 10, 20 and 30 for the heat transfer and the mechanical support of the semiconductor dies 10, 20 and 30.

FIG. 3 illustrates a disposition DST1 of the thermal-mechanical bumps TMBMP corresponding to the first bump layer 15 and FIG. 4 illustrates a disposition DST2 of the thermal-mechanical bumps TMBMP corresponding to the second bump layer 25. The disposition DST1 of the first bump layer 15 represents a case in which the number or the density of the thermal-mechanical bumps TMBMP is relatively high and the disposition DST2 of the second bump layer 25 represents a case in which the number or the density of the thermal-mechanical bumps TMBMP is relatively low. When the second semiconductor die 20 includes the heat source, the heat amount transferred from the second semiconductor die 20 to the third semiconductor die 30 is less than the heat amount transferred from the second semiconductor die 20 to the first semiconductor die 10 because the number of the thermal-mechanical bumps TMBMP is smaller in the second bump layer 25 than in the first bump layer 15. As such, the heat amounts transferred between the semiconductor dies 10, 20 and 30 may be adjusted by changing the disposition or the structure of the thermal-mechanical bumps TMBMP with respect to the bump layers 15 and 25.

According to an exemplary embodiment of the inventive concept, in designing the stacked semiconductor device STC1, the thermal-mechanical bumps TMBMP may be disposed uniformly regardless of the heat source, and then, the disposition and the structure of the thermal-mechanical bumps TMBMP may be changed based on the location of the heat source.

For example, the disposition DST1 of FIG. 3 may be set as a basic disposition and the disposition DST1 may be applied to all bump layers including the first and second bump layers 15 and 25. If the second semiconductor die 20 includes the heat source and the third semiconductor die 30 includes a heat-vulnerable region, the disposition of the second bump layer 25 may be changed from the disposition DST1 of FIG. 3 to the disposition DST2 of FIG. 4. As such, the overall performance of the stacked semiconductor device STC1 may be increased by changing the disposition or the structure of the thermal-mechanical bumps TMBMP to decrease the heat transfer from the second semiconductor die 20 including the heat source to the third semiconductor die 30 including the heat-vulnerable region.

As another example, the disposition DST2 of FIG. 4 may be set as a basic disposition and the disposition DST2 may be applied to all bump layers including the first and second bump layers 15 and 25. If the second semiconductor die 20 includes the heat source and the first semiconductor die 10 is not vulnerable to heat, the disposition of the first bump layer 15 may be changed from the disposition DST2 of FIG. 4 to the disposition DST1 of FIG. 3. As such, the overall performance of the stacked semiconductor device STC1 may be increased by changing the disposition or the structure of the thermal-mechanical bumps TMBMP to increase the heat transfer from the second semiconductor die 20 including the heat source to the first semiconductor die 10 that is impervious to heat.

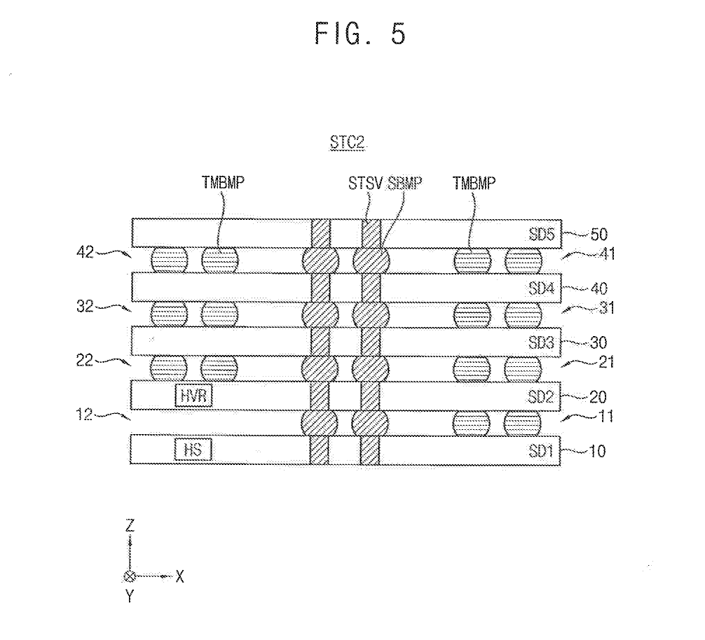

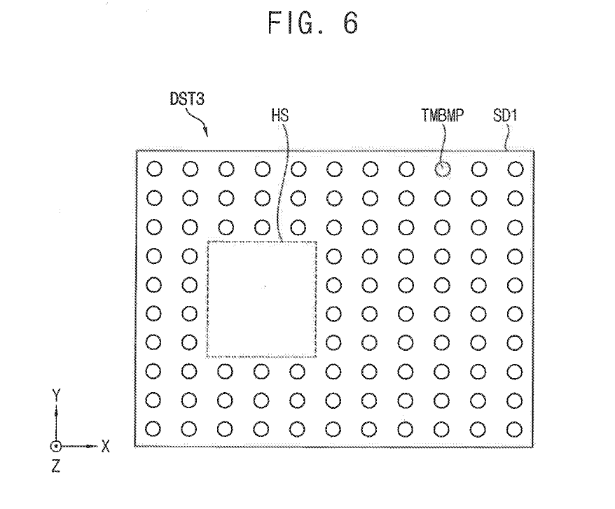

FIG. 5 is a cross-sectional view of a stacked semiconductor device according to an exemplary embodiment of the inventive concept, and FIG. 6 is a diagram illustrating a disposition of bumps in the stacked semiconductor device of FIG. 5 according to an exemplary embodiment of the inventive concept.

Referring to FIG. 5, a stacked semiconductor device STC2 may include first, second, third, fourth and fifth semiconductor dies SD1 (10), SD2 (20), SD3 (30), SD4 (40) and SD5 (50) stacked in the vertical direction Z, signal bumps SBMP and thermal-mechanical bumps TMBMP. FIG. 5 illustrates five semiconductor dies for convenience of illustration but the number of the stacked semiconductor dies may be changed variously.

The signal bumps SBMP may transfer electrical signals and/or power between the semiconductor dies 10, 20, 30, 40 and 50. For example, the signal bumps SBMP may be electrically connected to vertical contacts such as through-substrate vias STSV. The thermal-mechanical bumps TMBMP may be disposed in bump layers between the semiconductor dies 10, 20, 30, 40 and 50 for the heat transfer and the mechanical support of the semiconductor dies 10, 20, 30, 40 and 50. As illustrated in FIG. 5, the bump layers may include a first bump layer 11, 12 on the first semiconductor die 10, a second bump layer 21, 22 on the second semiconductor die 20, a third bump layer 31, 32 on the third semiconductor die 30 and a fourth bump layer 41, 42 on the fourth semiconductor die 40. For convenience of description, the bump layers may include first portions 12, 22, 32 and 42 corresponding to the heat source HS or near the heat source HS and second portions 11, 21, 31 and 41 other than the first portions 12, 22, 32 and 42, respectively.

FIG. 6 illustrates a disposition DST3 of the thermal-mechanical bumps TMBMP corresponding to the first bump layer 11, 12 on the first semiconductor die SD1. The dispositions of the second bump layer 21, 22, the third bump layer 31, 32 and the fourth bump layer 41, 42 may be the same as the basic disposition DST1 of FIG. 3.

In an exemplary embodiment of the inventive concept, the number of the thermal-mechanical bumps TMBMP in the bump layer in the upward direction +Z or in the downward direction −Z from the semiconductor die including the heat source may be decreased at an area near the heat source HS to be lower than the number of the thermal-mechanical bumps TMBMP in other areas. For example, as illustrated in FIGS. 5 and 6, when the first semiconductor die 10 includes the heat source HS and the second semiconductor die 20 includes a heat-vulnerable region HVR, the thermal-mechanical bumps TMBMP at the area 12 near the heat source in the first bump layer 11, 12 may be removed. As such, the thermal-mechanical bumps TMBMP at the area 12 corresponding to the heat source HS in the bump layer may be removed to decrease the heat transfer from the first semiconductor die 10 including the heat source HS to the second semiconductor die 20 including the heat-vulnerable region HVR, and thus, the overall performance of the stacked semiconductor device STC2 may be increased.

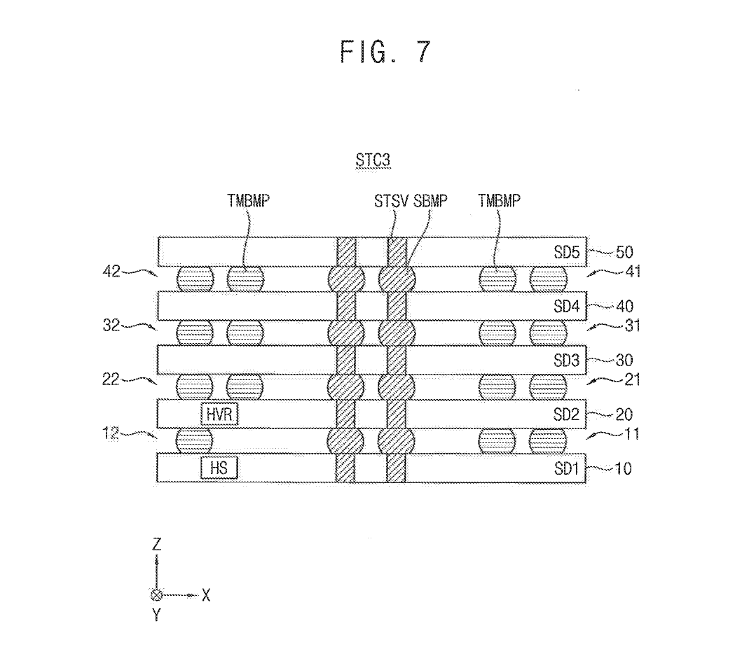

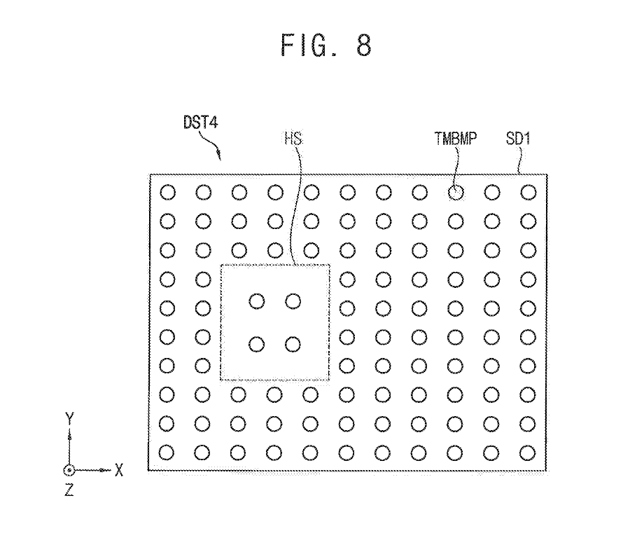

FIG. 7 is a cross-sectional view of a stacked semiconductor device according to an exemplary embodiment of the inventive concept, and FIG. 8 is a diagram illustrating a disposition of bumps in the stacked semiconductor device of FIG. 7 according to an exemplary embodiment of the inventive concept.

Referring to FIG. 7, a stacked semiconductor device STC3 may include first, second, third, fourth and fifth semiconductor dies SD1 (10), SD2 (20), SD3 (30), SD4 (40) and SD5 (50) stacked in the vertical direction Z, signal bumps SBMP and thermal-mechanical bumps TMBMP. FIG. 7 illustrates five semiconductor dies for convenience of illustration but the number of the stacked semiconductor dies may be changed variously.

FIG. 8 illustrates a disposition DST4 of the thermal-mechanical bumps TMBMP corresponding to a first bump layer 11, 12 on the first semiconductor die SD1. The dispositions of a second bump layer 21, 22, a third bump layer 31, 32 and a fourth bump layer 41, 42 may be the same as the basic disposition DST1 of FIG. 3.

In an exemplary embodiment of the inventive concept, the number of the thermal-mechanical bumps TMBMP in the bump layer in the upward direction +Z or in the downward direction −Z from the semiconductor die including the heat source may be decreased at an area near the heat source to be lower than the number of the thermal-mechanical bumps TMBMP in other areas.

For example, as illustrated in FIGS. 7 and 8, when the first semiconductor die 10 includes a heat source HS and the second semiconductor die 20 includes a heat-vulnerable region HVR, the density of the thermal-mechanical bumps TMBMP in the first bump layer 11, 12 may be decreased at the area 12 near the heat source HS to be lower than at the area 11. As such, the thermal-mechanical bumps TMBMP at the area 12 corresponding to the heat source HS in the bump layer may be decreased to decrease the heat transfer from the first semiconductor die 10 including the heat source HS to the second semiconductor die 20 including the heat-vulnerable region HVR, and thus, the overall performance of the stacked semiconductor device STC3 may be increased.

An exemplary embodiment of the inventive concept in which the thermal-mechanical bumps TMBMP are removed is described with reference to FIGS. 5 and 6 and an exemplary embodiment of the inventive concept in which the number or the density of the thermal-mechanical bumps TMBMP is decreased is described with reference to FIGS. 7 and 8. Hereinafter, the process of decreasing the number of the thermal-mechanical bumps TMBMP may include removing the thermal-mechanical bumps TMBMP.

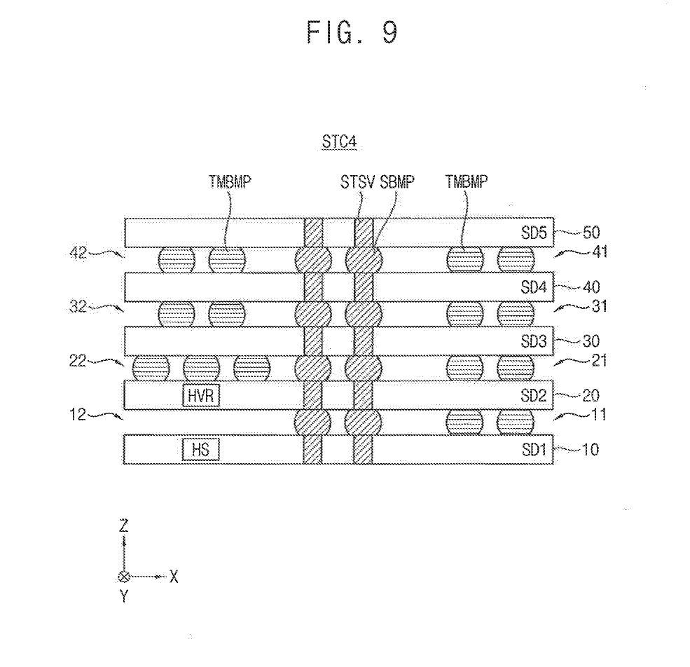

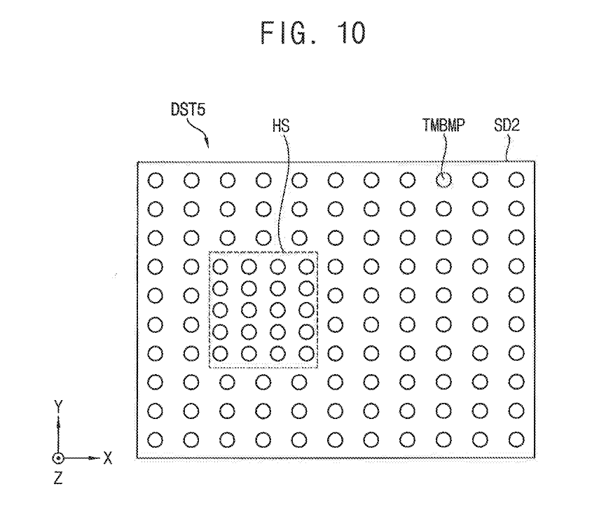

FIG. 9 is a cross-sectional view of a stacked semiconductor device according to an exemplary embodiment of the inventive concept, and FIG. 10 is a diagram illustrating a disposition of bumps in the stacked semiconductor device of FIG. 9 according to an exemplary embodiment of the inventive concept.

Referring to FIG. 9, a stacked semiconductor device STC4 may include first, second, third, fourth and fifth semiconductor dies SD1 (10), SD2 (20), SD3 (30), SD4 (40) and SD5 (50) stacked in the vertical direction Z, signal bumps SBMP and thermal-mechanical bumps TMBMP. FIG. 9 illustrates five semiconductor dies for convenience of illustration but the number of the stacked semiconductor dies may be changed variously.

FIG. 10 illustrates a disposition DST5 of the thermal-mechanical bumps TMBMP corresponding to a second bump layer 21, 22 on the second semiconductor die SD2. The disposition of a first bump layer 11, 21 may be the same as the disposition DST4 of FIG. 8 and the dispositions of a third bump layer 31, 32 and a fourth bump layer 41, 42 may be the same as the basic disposition DST1 of FIG. 3.

In an exemplary embodiment of the inventive concept, the number of the thermal-mechanical bumps TMBMP in the bump layer in the upward direction +Z or in the downward direction −Z from the semiconductor die including a heat source HS may be decreased at an area near the heat source to be lower than the number of the thermal-mechanical bumps TMBMP in other areas. Further the number of the thermal-mechanical bumps TMBMP in the bump layer in the upward direction +Z or in the downward direction −Z from the semiconductor die including a heat-vulnerable region HVR may be increased at an area corresponding to the heat source HS to be lower than in other areas.

For example, as described with reference to FIGS. 5 through 8, when the first semiconductor die 10 includes the heat source HS and the second semiconductor die 20 includes the heat-vulnerable region HVR, the density of the thermal-mechanical bumps TMBMP in the first bump layer 11, 12 may be decreased at the area 12 near the heat source HS to be lower than at the area 11. In addition, as illustrated in FIGS. 9 and 10, the density of the thermal-mechanical bumps TMBMP in the second bump layer 21, 22 may be increased at the area 22 corresponding to the heat source HS to be higher than at the area 21. The decrease of the bump density at the area 12 in the first bump layer 11, 12 is to suppress the heat transfer from the heat source HS to the heat-vulnerable region HVR and the increase of the bump density at the area 22 in the second bump layer 21, 22 is to expedite the heat dissipation from the heat-vulnerable region HVR. As such, the thermal-mechanical bumps TMBMP at the area 12 in the first bump layer may be decreased and the thermal-mechanical bumps TMBMP at the area 22 in the second bump layer may be increased to lower the temperature of the heat-vulnerable region HVR in the second semiconductor die 20, and thus, the overall performance of the stacked semiconductor device STC4 may be increased.

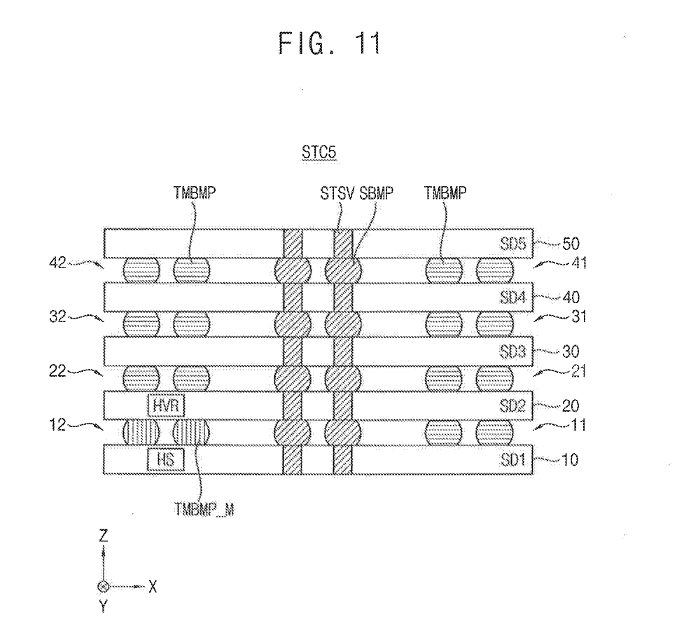

FIGS. 11, 12, 13 and 14 are cross-sectional views of a stacked semiconductor device according to example embodiments of the inventive concept.

Referring to FIG. 11, a stacked semiconductor device STC5 may include first, second, third, fourth and fifth semiconductor dies SD1 (10), SD2 (20), SD3 (30), SD4 (40) and SD5 (50) stacked in the vertical direction Z, signal bumps SBMP and thermal-mechanical bumps TMBMP. FIG. 11 illustrates five semiconductor dies for convenience of illustration but the number of the stacked semiconductor dies may be changed variously.

The dispositions of a first bump layer 11, 12, a second bump layer 21, 22, a third bump layer 31, 32 and a fourth bump layer 41, 42 may be the same as the basic disposition DST1 of FIG. 3.

In an exemplary embodiment of the inventive concept, the thermal conductivity of the thermal-mechanical bumps TMBMP in the bump layer in the upward direction +Z or in the downward direction −Z from the semiconductor die including a heat source HS may be decreased at an area near the heat source HS to be lower than the number of the thermal-mechanical bumps TMBMP in other areas.

For example, as illustrated in FIG. 11, when the first semiconductor die 10 includes the heat source HS and the second semiconductor die 20 includes a heat-vulnerable region HVR, the thermal conductivity of the thermal-mechanical bumps TMBMP_M at the area 12 near the heat source HS in the first bump layer 11, 12 may be decreased to be lower than the thermal conductivity of the thermal-mechanical bumps TMBMP at the area 11 in the first bump layer 11, 12. When the number of the thermal-mechanical bumps TMBMP may not be decreased due to the need for mechanical support, the thermal conductivity of the thermal-mechanical bumps TMBMP may be decreased instead of the number or the density of the thermal-mechanical bumps TMBMP. As such, the thermal conductivity of the thermal-mechanical bumps TMBMP_M at the area 12 corresponding to the heat source HS in the bump layer may be decreased to decrease the heat transfer from the first semiconductor die 10 including the heat source HS to the second semiconductor die 20 including the heat-vulnerable region HVR, and thus, the overall performance of the stacked semiconductor device STC5 may be increased.

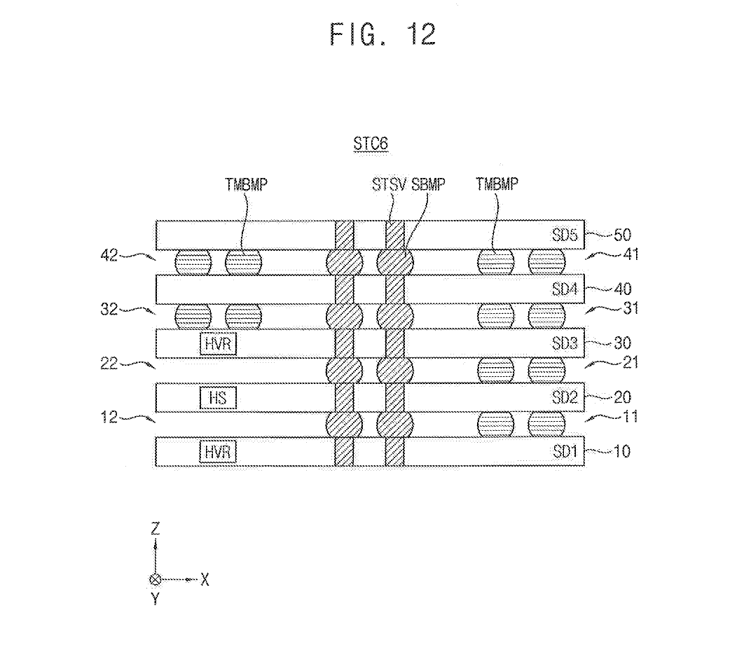

Referring to FIG. 12, a stacked semiconductor device STC6 may include first, second, third, fourth and fifth semiconductor dies SD1 (10), SD2 (20), SD3 (30), SD4 (40) and SD5 (50) stacked in the vertical direction Z, signal bumps SBMP and thermal-mechanical bumps TMBMP. FIG. 12 illustrates five semiconductor dies for convenience of illustration but the number of the stacked semiconductor dies may be changed variously.

The dispositions of a first bump layer 11, 12 and a second bump layer 21, 22 may be the same as one of the dispositions DST3 and DST4 of FIGS. 6 and 8, and the dispositions of a third bump layer 31, 32 and a fourth bump layer 41, 42 may be the same as the basic disposition DST1 of FIG. 3.

In an exemplary embodiment of the inventive concept, the density of the thermal-mechanical bumps TMBMP in the bump layers in the upward direction +Z and in the downward direction −Z from the semiconductor die including a heat source HS may be decreased at an area near the heat source HS to be lower than the number of the thermal-mechanical bumps TMBMP in other areas.

For example, as illustrated in FIG. 12, when the second semiconductor die 20 includes the heat source HS and the first and third semiconductor dies 10 and 30 include a heat-vulnerable regions HVR respectively, the density of the thermal-mechanical bumps TMBMP in the first bump layer 11, 12 and the second bump layer 21, 22 may be decreased at the areas 12 and 22 near the heat source HS to be lower than at the areas 11 and 13. As such, the thermal-mechanical bumps TMBMP at the areas 12 and 22 corresponding to the heat source HS in the bump layers may be decreased to decrease the heat transfer from the second semiconductor die 20 including the heat source HS to the first and third semiconductor dies 10 and 30 including the heat-vulnerable regions HVR, and thus, the overall performance of the stacked semiconductor device STC6 may be increased.

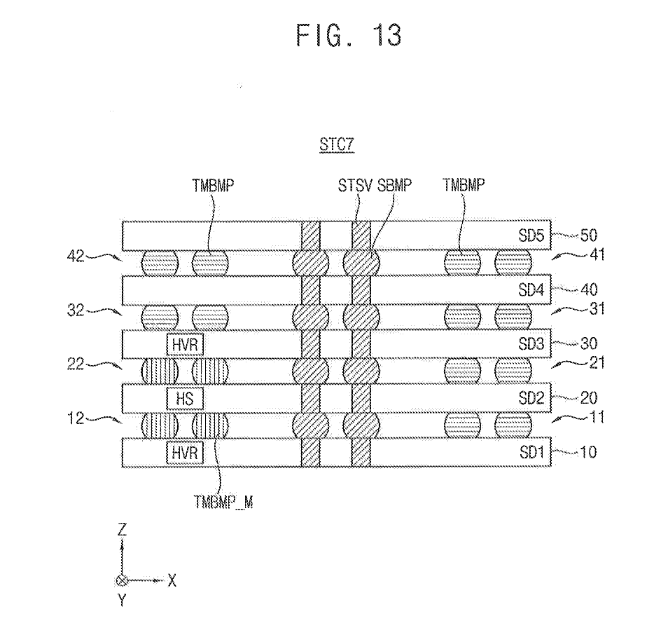

Referring to FIG. 13, a stacked semiconductor device STC7 may include first, second, third, fourth and fifth semiconductor dies SD1 (10), SD2 (20), SD3 (30), SD4 (40) and SD5 (50) stacked in the vertical direction Z, signal bumps SBMP and thermal-mechanical bumps TMBMP. FIG. 13 illustrates five semiconductor dies for convenience of illustration but the number of the stacked semiconductor dies may be changed variously.

The dispositions of a first bump layer 11, 12, a second bump layer 21, 22, a third bump layer 31, 32 and a fourth bump layer 41, 42 may be the same as the basic disposition DST1 of FIG. 3.

In an exemplary embodiment of the inventive concept, the thermal conductivity of the thermal-mechanical bumps in the bump layers in the upward direction +Z and in the downward direction −Z from the semiconductor die including a heat source HS may be decreased at an area near the heat source HS to be lower than the number of the thermal-mechanical bumps TMBMP in other areas.

For example, as illustrated in FIG. 13, when the second semiconductor die 20 includes the heat source HS and the first and third semiconductor dies 10 and 30 include heat-vulnerable regions HVR respectively, the thermal conductivity of the thermal-mechanical bumps TMBMP_M at the areas 12 and 22 near the heat source HS in the first bump layer 11, 12 and the second bump layer 21, 22 may be decreased to be lower than the thermal conductivity of the thermal-mechanical bumps TMBMP at the areas 11 and 21 in the first bump layer 11, 12 and the second bump layer 21, 22. As such, the thermal conductivity of the thermal-mechanical bumps TMBMP_M at the areas 12 and 22 corresponding to the heat source HS in the bump layers may be decreased to decrease the heat transfer from the second semiconductor die 20 including the heat source HS to the first and third semiconductor dies 10 and 30 including the heat-vulnerable regions HVR, and thus, the overall performance of the stacked semiconductor device STC7 may be increased.

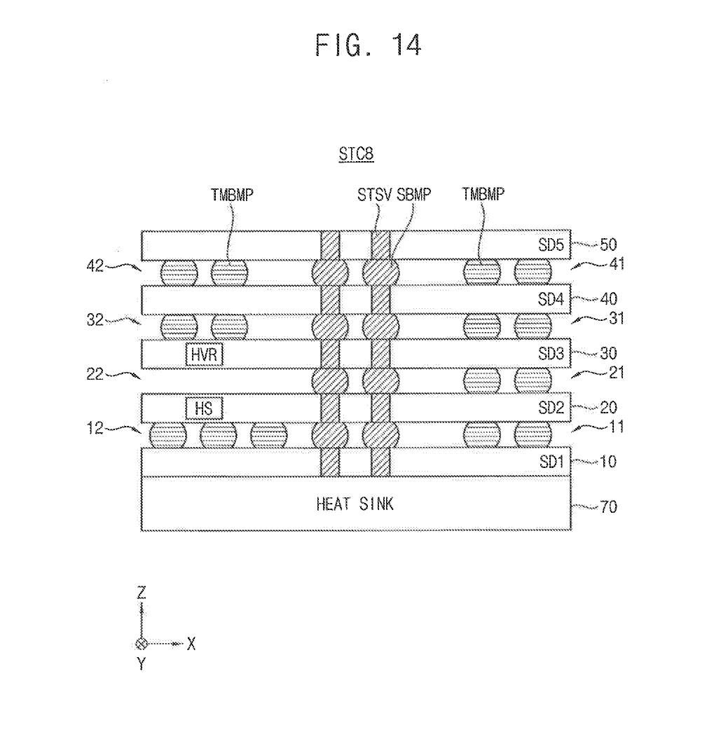

Referring to FIG. 14, a stacked semiconductor device STC8 may include first, second, third, fourth and fifth semiconductor dies SD1 (10), SD2 (20), SD3 (30), SD4 (40) and SD5 (50) stacked in the vertical direction Z, signal bumps SBMP, thermal-mechanical bumps TMBMP and a heat spreader or heat sink 70. FIG. 14 illustrates five semiconductor dies for convenience of illustration but the number of the stacked semiconductor dies may be changed variously.

The disposition of a first bump layer 11, 12 may be the same as the disposition DST5 of FIG. 10, the disposition of a second bump layer 21, 22 may be the same as the dispositions one of the dispositions DST3 and DST4 of FIGS. 6 and 8, and the dispositions of a third bump layer 31, 32 and a fourth bump layer 41, 42 may be the same as the basic disposition DST1 of FIG. 3.

In an exemplary embodiment of the inventive concept, the number of the thermal-mechanical bumps TMBMP in the bump layer in the upward direction +Z or in the downward direction −Z from the semiconductor die including a heat source HS may be decreased at an area near the heat source HS to be lower than the number of the thermal-mechanical bumps TMBMP in other areas. Further the number of the thermal-mechanical bumps TMBMP in the bump layer in the upward direction +Z or in the downward direction −Z from the semiconductor die including a heat-vulnerable region HVR may be increased at an area corresponding to the heat source HS to be lower than the number of the thermal-mechanical bumps TMBMP in other areas.

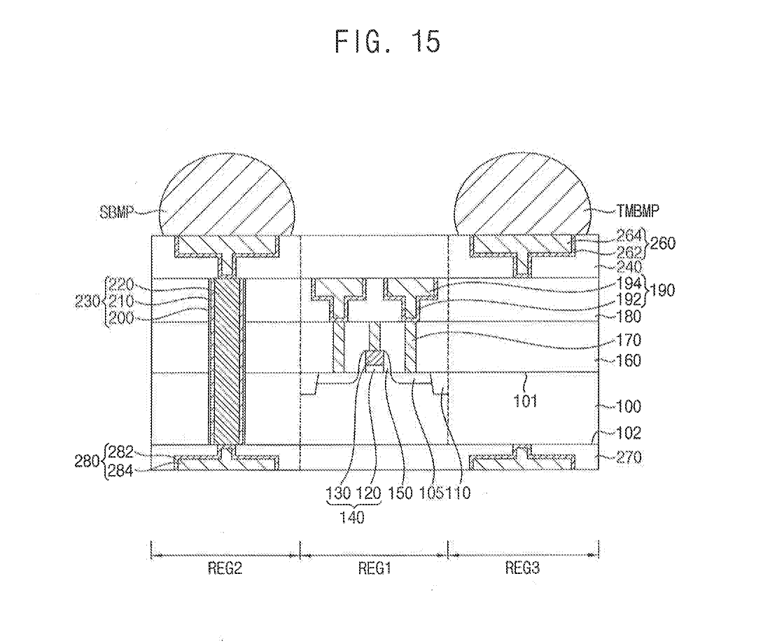

For example, as illustrated in FIG. 15, when the second semiconductor die 20 includes the heat source HS and the third semiconductor die 30 includes the heat-vulnerable region HVR, the density of the thermal-mechanical bumps TMBMP in the second bump layer 21, 22 may be decreased at the area 22 near the heat source HS to be lower than at the area 21. In addition, the density of the thermal-mechanical bumps TMBMP in the first bump layer 11, 12 may be increased at the area 12 corresponding to the heat source HS to be higher than at the area 11. The decrease of the bump density at the area 22 in the second bump layer 21, 22 is to suppress the heat transfer from the heat source HS to the heat-vulnerable region HVR and the increase of the bump density at the area 12 in the second bump layer 11, 12 is to expedite the heat dissipation from the heat source HS to the heat sink 70. As such, the thermal-mechanical bumps TMBMP at the area 22 in the second bump layer 21, 22 may be decreased to decrease the heat transfer from the second semiconductor die 20 including the heat source HS to the third semiconductor die 30 including the heat-vulnerable region HVR and the thermal-mechanical bumps TMBMP at the area 12 in the first bump layer 11, 12 may be increased to increase the heat transfer from the second semiconductor die 20 including the heat source HS to the heat sink 70, and thus, the overall performance of the stacked semiconductor device STC8 may be increased.

FIG. 15 is a cross-sectional view illustrating a structure of a semiconductor device including a thermal-mechanical bump according to an exemplary embodiment of the inventive concept.

Referring to FIG. 15, a semiconductor device may include a via structure 230 passing through a substrate 100, a pad structures 260 and 280 and bumps SBMP and TMBMP. The semiconductor device may further include first, second, third and fourth insulating interlayers 160, 180, 240 and 270, circuit elements, wirings 190 and contact plugs 170.

The substrate 100 may include silicon, germanium, silicon-germanium, or III-V compounds, e.g., GaP, GaAs, GaSb, etc. In an exemplary embodiment of the inventive concept, the substrate 100 may be a silicon-on-insulator (SOI) substrate, or a germanium-on-insulator (GOI) substrate.

The substrate 100 may have a first surface 101 and a second surface 102 opposite thereto. The substrate 100 may include a first region REG1, a second region REG2 and a third region REG3. The first region REG1 may be a circuit region in which the circuit elements may be formed, the second region REG2 may be a via region in which the via structure 230 may be formed and the third region REG3 may be a thermal-mechanical region in which the thermal-mechanical bumps TMBMP may be formed.

In the first region REG1, an isolation layer 110 including an insulating material, e.g., silicon oxide, may be formed at a portion of the substrate 100 adjacent to the first surface, and circuit elements, e.g., a transistor, may be formed on the first surface 101 of the substrate 100. The transistor may include a gate structure 140 having a gate insulation layer pattern 120 and a gate electrode 130 sequentially stacked on the first surface 101 of the substrate 100, and an impurity region 105 at a portion of the substrate 100 adjacent to the gate structure 140. A gate spacer 150 may be formed on a sidewall of the gate structure 140.

The gate insulation layer pattern 120 may include an oxide, e.g., silicon oxide or a metal oxide, the gate electrode 130 may include, e.g., doped polysilicon, a metal, a metal nitride and/or a metal silicide, and the gate spacer 150 may include a nitride, e.g., silicon nitride.

In an exemplary embodiment of the inventive concept, a plurality of transistors may be formed on the first surface 101 of the substrate 100 in the first region REG1. The circuit elements may not be limited to the transistors, but various types of circuit elements, e.g., diodes, resistors, inductors, capacitors, etc., may be formed in the first region REG1.

The first, second and third insulating interlayers 160, 180 and 240 may be sequentially formed on the first surface 101 of the substrate 100 and the forth insulating interlayer 270 may be formed on the second surface 102 of the substrate 100.

The first insulating interlayer 160 may cover the circuit elements, and the contact plug 170 contacting the impurity region 105 may be formed through the first insulating interlayer 160. Alternatively, the contact plug 170 may be formed through the first insulating interlayer 160 to contact the gate structure 140. The first insulating interlayer 160 may include an oxide, e.g., silicon oxide, and the contact plug 170 may include, e.g., a metal, a metal nitride, a metal silicide, doped polysilicon, etc.

The second insulating interlayer 180 may contain the wiring 190 passing therethrough, which may contact the contact plug 170. The second insulating interlayer 180 may include a low-k dielectric material, e.g., silicon oxide doped with fluorine or carbon, a porous silicon oxide, spin on organic polymer, or an inorganic polymer, e.g., hydrogen silsesquioxane (HSSQ), methyl silsesquioxane (MSSQ), etc.

In an exemplary embodiment of the inventive concept, the wiring 190 may include a first conductive pattern 194 and a first barrier pattern 192 partially covering the first conductive pattern 194. The first conductive pattern 194 may include a metal, e.g., copper, aluminum, tungsten, titanium, tantalum, etc., and the first barrier pattern 192 may include a metal nitride, e.g., titanium nitride, tantalum nitride, tungsten nitride, copper nitride, aluminum nitride, etc. In an exemplary embodiment of the inventive concept, the wiring 190 may be formed by a double damascene process, and thus, upper and lower portions of the wiring 190 may have different widths from each other. Alternatively, the wiring 190 may be formed by a single damascene process, and thus, the wiring 190 may have a substantially constant width regardless of the height thereof.

The via structure 230 may be formed through the first and second insulating interlayers 160 and 180 and the substrate 100, and a portion of the via structure 230 may be exposed over the second surface 102 of the substrate 100. The via structure 230 may have a top surface of which a central portion may be concave.

In an exemplary embodiment of the inventive concept, the via structure 230 may include a via electrode and an insulation layer pattern 200 surrounding a sidewall of the via electrode. The via electrode may include a second conductive pattern 220 and a second barrier layer pattern 210 surrounding a sidewall of the second conductive pattern 220. The second conductive pattern 220 may include a metal, e.g., copper, aluminum, tungsten, etc., or doped polysilicon, and the second barrier pattern 210 may include a metal nitride, e.g., titanium nitride, tantalum nitride, tungsten nitride, copper nitride, aluminum nitride, etc. The insulation layer pattern 200 may include an oxide, e.g., silicon oxide, or a nitride, e.g., silicon nitride.

The third insulating interlayer 240 and the fourth insulating interlayer 270 may contain the pad structures 260 and 280, respectively. The third insulating interlayer 240 and the fourth insulating interlayer 270 may include a low-k dielectric material, e.g., silicon oxide doped with fluorine or carbon, a porous silicon oxide, a spin on organic polymer, or an inorganic polymer, e.g., HSSQ, MSSQ, etc.

The pad structures 260 and 280 may be formed by a double damascene process or a single damascene process similarly as the wiring 190. In an exemplary embodiment of the inventive concept, the pad structures 260 and 280 may include conductive patterns 264 and 284 and barrier layer patterns 262 and 282 partially covering the conductive pattern 264 and 284, respectively.

The signal bump SBMP and the thermal-mechanical bumps TMBMP may contact the pad structures 260. For example, and the bumps SBMP and TMBMP may include a metal, e.g., silver, copper, etc., or an alloy, e.g., solder. As illustrated in FIG. 15, the signal bump SBMP may be electrically connected to the vertical contact such as the through-substrate via 230. In contrast, the thermal-mechanical bump TMBMP may not be electrically connected to the vertical contact.

FIGS. 16, 17, 18, 19 and 20 are cross-sectional views illustrating stages of a method of manufacturing the semiconductor device of FIG. 15 according to an exemplary embodiment of the inventive concept.

Referring to FIG. 16, circuit elements and a contact plug 170 may be formed on a substrate 100 having an isolation layer 110 thereon.

The substrate 100 may include silicon, germanium, silicon-germanium, or III-V compounds, e.g., GaP, GaAs, GaSb, etc. In an exemplary embodiment of the inventive concept, the substrate 100 may be a silicon-on-insulator (SOI) substrate, or a germanium-on-insulator (GOI) substrate. The substrate 100 may have a first surface 101 and a second surface 102 opposite thereto.

In an exemplary embodiment of the inventive concept, the isolation layer 110 may be formed by a shallow trench isolation (STI) process, and include an insulating material, e.g., silicon oxide.

A transistor serving as the circuit element may be formed by the following method.

For example, after sequentially forming a gate insulation layer and a gate electrode layer on the first surface 101 of the substrate 100 having the isolation layer 110 thereon, the gate electrode layer and the gate insulation layer may be patterned by a photolithography process to form a gate structure 140 including a gate insulation layer pattern 120 and a gate electrode 130 sequentially stacked on the first surface 101 of the substrate 100 in the first region REG1. The gate insulation layer may be formed to include an oxide, e.g., silicon oxide or a metal oxide, and the gate electrode layer may be formed to include, e.g., doped polysilicon, a metal, a metal nitride and/or a metal silicide.

A gate spacer layer may be formed on the substrate 100 and the isolation layer 110 to cover the gate structure 140, and may be anisotropically etched to form a gate spacer 150 on a sidewall of the gate structure 140. The gate spacer layer may be formed to include a nitride, e.g., silicon nitride.

Impurities may be implanted into an upper portion of the substrate 100 to form a first impurity region 105, so that the transistor including the gate structure 140 and the first impurity region 105 may be formed.

In an exemplary embodiment of the inventive concept, a plurality of transistors may be formed on the substrate 100 in the first region REG1. The circuit elements may not be limited to the transistor, but various types of circuit elements, e.g., diodes, resistors, inductors, capacitors, etc. may be formed.

A first insulating interlayer 160 may be formed on the substrate 100 to cover the circuit elements, and the contact plug 170 may be formed through the first insulating interlayer 160 to contact the first impurity region 105. Alternatively, the contact plug 170 may be formed through the first insulating interlayer 160 to contact the gate structure 140.

The first insulating interlayer 160 may be formed to include an oxide, e.g., silicon oxide. The contact plug 170 may be formed by forming a contact hole through the first insulating interlayer 160 to expose the first impurity region 105, forming a conductive layer on the exposed first impurity region 105 and the first insulating interlayer 160 to fill the contact hole, and planarizing an upper portion of the conductive layer until a top surface of the first insulating interlayer 160 may be exposed. The conductive layer may be formed to include, e.g., a metal, a metal nitride, a metal silicide, doped polysilicon, etc.

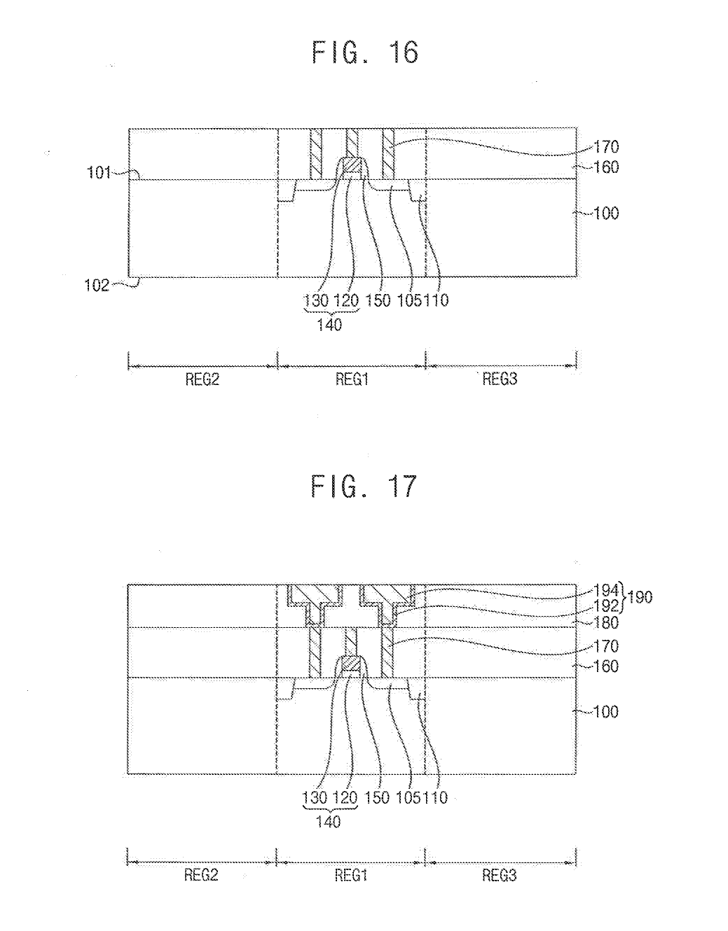

Referring to FIG. 17, a second insulating interlayer 180 may be formed on the first insulating interlayer 160 and the contact plug 170 and at least one wiring 190 may be formed through the second insulating interlayer 180 in the first region REG1.

The second insulating interlayer 180 may be formed to include a low-k dielectric material, e.g., silicon oxide doped with fluorine or carbon, a porous silicon oxide, a spin on organic polymer, or an inorganic polymer, e.g., hydrogen silsesquioxane (HSSQ), methyl silsesquioxane (MSSQ), etc.

In an exemplary embodiment of the inventive concept, the wiring 190 may be formed by a double damascene process as follows.

After partially removing the second insulating interlayer 180 to form a via hole therethrough, which may expose top surfaces of the first insulating interlayer 160 and the contact plug 170, an upper portion of the second insulating interlayer 180 may be removed to form a first trench in communication with the via hole and having a diameter greater than that of the via hole. Alternatively, after forming the first trench, the via hole may be formed later. A first barrier layer may be formed on inner walls of the via hole and the first trench and the exposed top surfaces of the first insulating interlayer 160 and the contact plug 170, and a first conductive layer may be formed on the first barrier layer to sufficiently fill remaining portions of the via hole and the first trench. Upper portions of the first barrier layer and the first conductive layer may be planarized until a top surface of the second insulating interlayer 180 may be exposed to form the wiring 190 contacting the top surface of the contact plug 170 in the first region REG1. The wiring 190 may be formed to include a first conductive pattern 194 and a first barrier layer pattern 192 surrounding a bottom and a sidewall of the first conductive pattern 194.

The first barrier layer may be formed to include a metal nitride, e.g., titanium nitride, tantalum nitride, tungsten nitride, copper nitride, aluminum nitride, etc., and the first conductive layer may be formed to include a metal, e.g., copper, aluminum, tungsten, titanium, tantalum, etc. When the first conductive layer is formed using copper or aluminum, a seed layer may be formed on the first barrier layer, and the first conductive layer may be formed by an electroplating process.

As described above, the wiring 190 may be formed by a double damascene process, and thus, may be formed to have a lower portion and an upper portion connected thereto. Alternatively, the wiring 190 may be formed by a single damascene process. In this case, the wiring 190 may have a substantially constant thickness from a bottom portion toward a top portion thereof.

In FIG. 17, the wiring 190 may be formed through the single second insulating interlayer 180, however, more insulating interlayers may be formed on the second insulating interlayer 180 and more wirings 190 may be formed through each of the insulating interlayers.

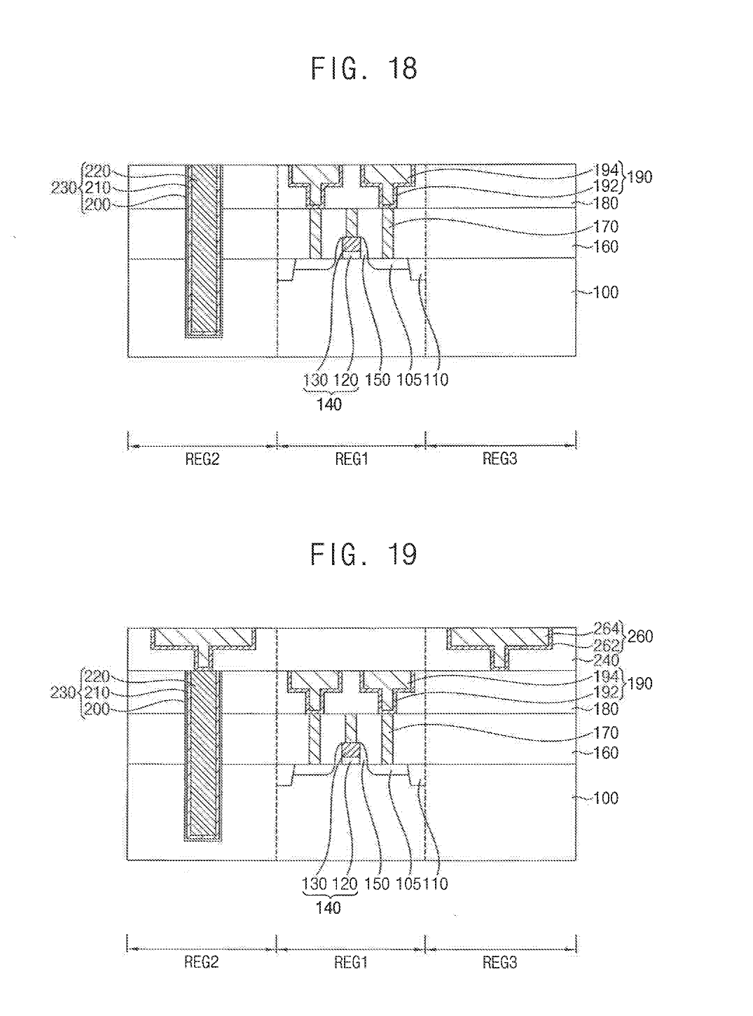

Referring to FIG. 18, a via structure 230 may be formed through a portion of the substrate 100.

For example, a first photoresist pattern covering the first region REG1 and the third region REG3 of the substrate 100 and partially exposing the second region REG2 of the substrate 100 may be formed on the second insulating interlayer 180 and the wiring 190, and the first and second insulating interlayers 160 and 180 and the substrate 100 may be etched using the first photoresist pattern as an etching mask to form a second trench. The second trench may be formed through the first and second insulating interlayers 160 and 180 and the portion of the substrate 100.

An insulation layer 200 and a second barrier layer 210 may be sequentially formed on an inner wall of the second trench, and a second conductive layer 220 may be formed on the second barrier layer 210 to sufficiently fill the second trench. The insulation layer 200 may be formed to include an oxide, e.g., silicon oxide or a nitride, e.g., silicon nitride, and the second barrier layer 210 may be formed to include a metal nitride, e.g., titanium nitride, tantalum nitride, tungsten nitride, copper nitride, aluminum nitride, etc. The second conductive layer 220 may be formed to include a metal, e.g., copper, aluminum, tungsten, etc., or doped polysilicon. When the second conductive layer 220 is formed to include copper or aluminum, a second seed layer may be formed on the second barrier layer 210, and the second conductive layer 220 may be formed by an electroplating process.

The second conductive layer 220, the second barrier layer 210 and the insulation layer 200 may be planarized until a top surface of the second insulating interlayer 180 may be exposed to form the via structure 230 filling the second trench. The via structure 230 may include the insulation layer 200, the second barrier layer 210 and the second conductive layer 220.

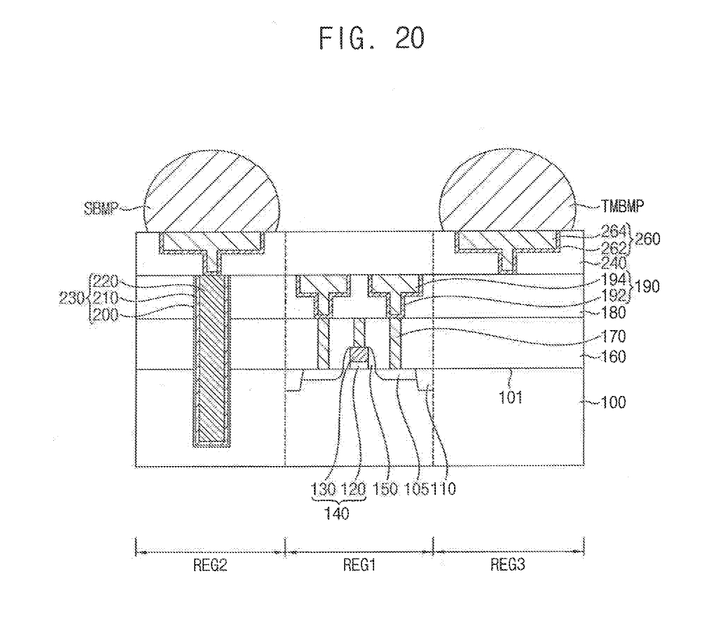

Referring to FIG. 19, a third insulating interlayer 240 may be formed on the second insulating interlayer 180, the wiring 190 and the via structure 230, and pad structures 260 may be formed through the third insulating interlayer 240 in the second and third regions REG2 and REG3, respectively.

The third insulating interlayer 240 may be formed to include a low-k dielectric material, e.g., silicon oxide doped with fluorine or carbon, a porous silicon oxide, a spin on organic polymer, or an inorganic polymer, e.g., hydrogen silsesquioxane (HSSQ), methyl silsesquioxane (MSSQ), etc.

The pad structures 260 may be formed by a double damascene process or a single damascene process, like the wiring 190. In an exemplary embodiment of the inventive concept, the pad structure 260 in the second region REG2 may be formed to contact a top surface of the via structure 230. The pad structures 260 may be formed to include a conductive pattern 264 and a barrier layer pattern 262 covering a bottom and a sidewall of the conductive pattern 264.

Referring to FIG. 20, the signal bumps SBMP and the thermal-mechanical bumps TMBMP may be formed on the third insulating interlayer 240 to contact the upper surfaces of the pad structures 260. The bumps SBMP and TMBMP may include a metal, e.g., silver, copper, etc., or an alloy, e.g., solder.

After the bumps SBMP and TMBMP are formed on the third insulating interlayer 240, the fourth insulating interlayer 270 may be formed on the second surface 102 of the substrate 100 and the pad structures 280 may be formed through the fourth insulating interlayer 270 in the second and third regions REG2 and REG3, respectively, in the same way as described with reference to FIG. 19. Refer to FIG. 15 to see the fourth insulating interlayer 270 and the pad structures 280.

The substrate 100 may be overturned using a handling substrate so that the second surface 102 of the substrate 100 may face upward. A portion of the substrate 100 adjacent to the second surface 102 may be removed to expose a portion of the via structure 230. Thus, the substrate 100 may be partially removed by, e.g., an etch back process.

The fourth insulating interlayer 270 may be formed to include a low-k dielectric material, e.g., silicon oxide doped with fluorine or carbon, a porous silicon oxide, a spin on organic polymer, or an inorganic polymer, e.g., hydrogen silsesquioxane (HSSQ), methyl silsesquioxane (MSSQ), etc.

The pad structures 280 may be formed by a double damascene process or a single damascene process, like the wiring 190. In an exemplary embodiment of the inventive concept, the pad structure 280 in the second region REG2 may be formed to contact a bottom surface of the via structure 230. The pad structures 280 may be formed to include a conductive pattern 284 and a barrier layer pattern 282 covering a bottom and a sidewall of the conductive pattern 284.

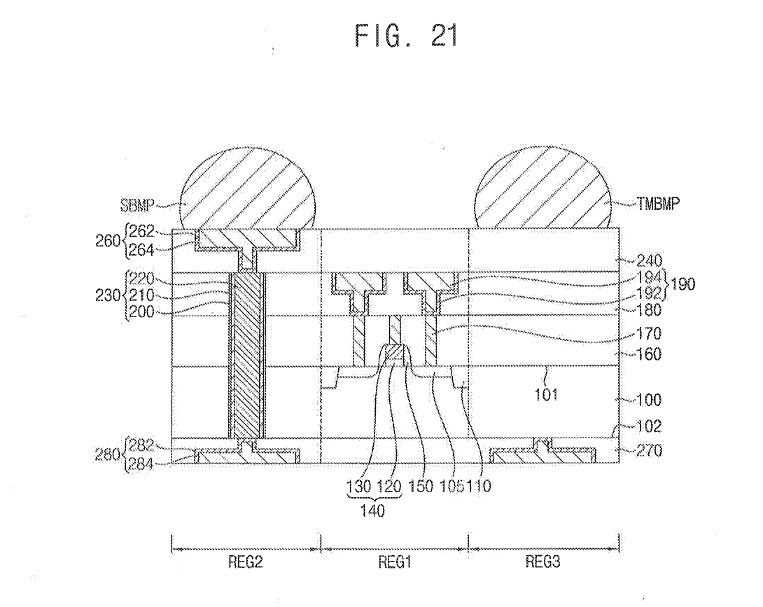

FIG. 21 is a cross-sectional view illustrating a structure of a semiconductor device including a thermal-mechanical bump according to an exemplary embodiment of the inventive concept. The structure of FIG. 21 is substantially the same as the structure of FIG. 15, and thus, repeated descriptions are omitted.

In comparison with FIG. 15, the bump pad 260 under the thermal-mechanical bumps TMBMP may be removed in the structure of FIG. 21.

In an exemplary embodiment of the inventive concept, the bump pads in the bump layer in the upward direction +Z or in the downward direction −Z from the semiconductor die including a heat source may be removed at an area near the heat source.

For example, the bump pads at a first area may be removed as illustrated in FIG. 21 instead of decreasing the thermal conductivity of the thermal-mechanical bumps TMBMP at the area 12 as described with reference to FIG. 11. As such, the bump pads at the first area 12 corresponding to the heat source HS in the bump layer may be removed to decrease the heat transfer from the first semiconductor die 10 including the heat source HS to the second semiconductor die 20 including the heat-vulnerable region HVR, and thus, the overall performance of the stacked semiconductor device STC5 in FIG. 11 may be increased.

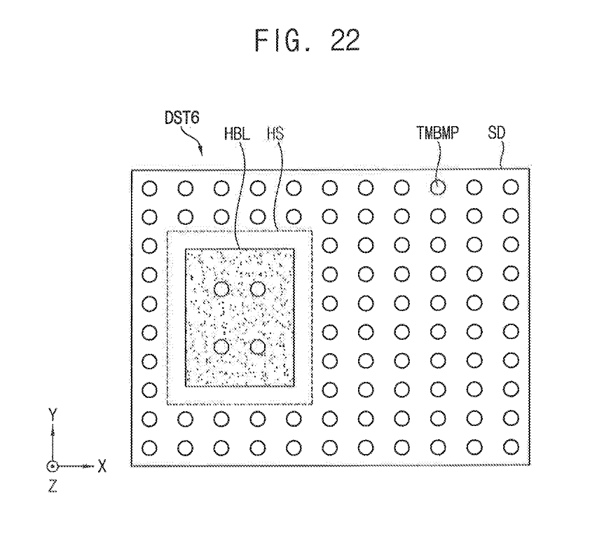

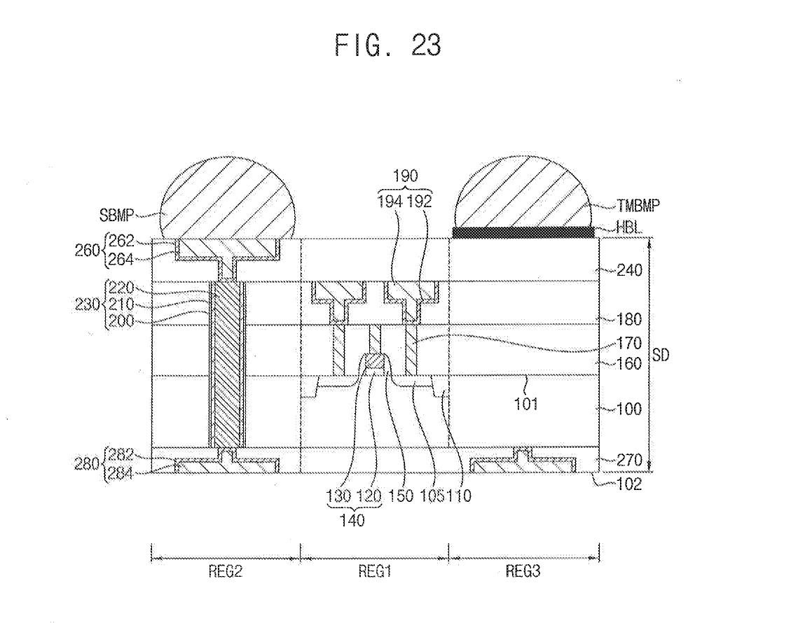

FIG. 22 is a diagram illustrating a disposition DST6 of thermal-mechanical bumps in a stacked semiconductor device according to an exemplary embodiment of the inventive concept, and FIG. 23 is a cross-sectional view illustrating a structure of the semiconductor device including the thermal-mechanical bump of FIG. 22 according to an exemplary embodiment of the inventive concept.

The structure of FIGS. 22 and 23 is substantially the same as described with reference to FIG. 15, and thus, repeated descriptions are omitted. In comparison with the structure of FIG. 15, the bump pad 260 under the thermal-mechanical bump TMBMP is omitted and a heat block layer HBL is added in the structure of FIGS. 22 and 23.

In an exemplary embodiment of the inventive concept, the heat block layer HBL may be coated on the top surface and/or the bottom surface of the semiconductor die including the heat source.

For example, as illustrated in FIGS. 22 and 23, the heat block layer HBL may be coated on the top surface near the heat source HS of the semiconductor die SD. The material of the heat block layer HBL may include an insulating material such as plastic. As such, the heat block layer HBL may be coated on the surface of the semiconductor die corresponding to the heat source HS to decrease the heat transfer from the semiconductor die SD including the heat source HS to the adjacent semiconductor die including a heat-vulnerable region HVR, and thus, the overall performance of the stacked semiconductor device may be increased.

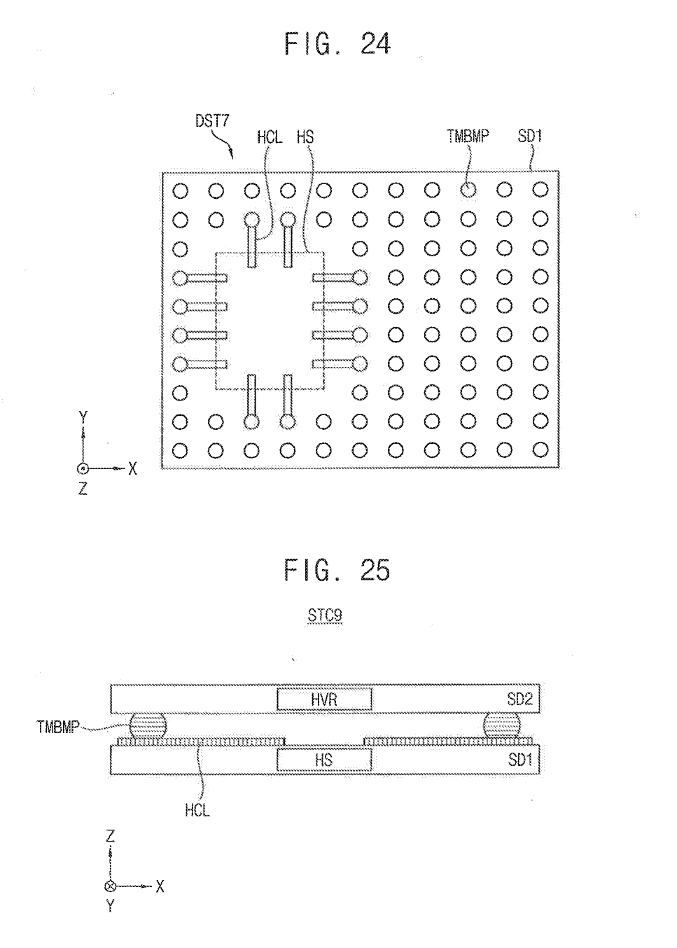

FIG. 24 is a diagram illustrating a disposition DST7 of bumps in a stacked semiconductor device according to an exemplary embodiment of the inventive concept, and FIG. 25 is a cross-sectional view illustrating a structure of the semiconductor device including the thermal-mechanical bump TMBMP of FIG. 24 according to an exemplary embodiment of the inventive concept.

Referring to FIGS. 24 and 25, a stacked semiconductor device STC9 may include a first semiconductor die SD1 including a heat source HS and a second semiconductor die SD2 including a heat-vulnerable region HVR, which is stacked on the first semiconductor die SD1. FIG. 25 illustrates two semiconductor dies for convenience of illustration but the number of the stacked semiconductor dies may be changed variously.

In an exemplary embodiment of the inventive concept, a heat conduction line HCL may be formed on a top surface or a bottom surface of the semiconductor die SD1 including the heat source HS such that a first end of the heat conduction line HCL contacts a portion near the heat source HS and a second end of the heat conduction line HCL is far from the heat source HS. The thermal-mechanical bump TMBMP may be removed from the first end of the heat conduction line HCL and the thermal-mechanical bump TMBMP may be disposed at the second end of the heat conduction line HCL.

For example, as illustrated in FIGS. 24 and 25, when the first semiconductor die SD1 includes the heat source HS and the second semiconductor die SD2 includes the heat-vulnerable regions HVR, the heat conduction lines HCL may be formed on the top surface of the first semiconductor die SD1. The heat transfer from the heat source HS to the heat-vulnerable region HVR may be decreased by removing the thermal-mechanical bump TMBMP from the first end of the heat conduction line HCL near the heat source HS and disposing the thermal-mechanical bump TMBMP on the second end of the heat conduction line HCL.

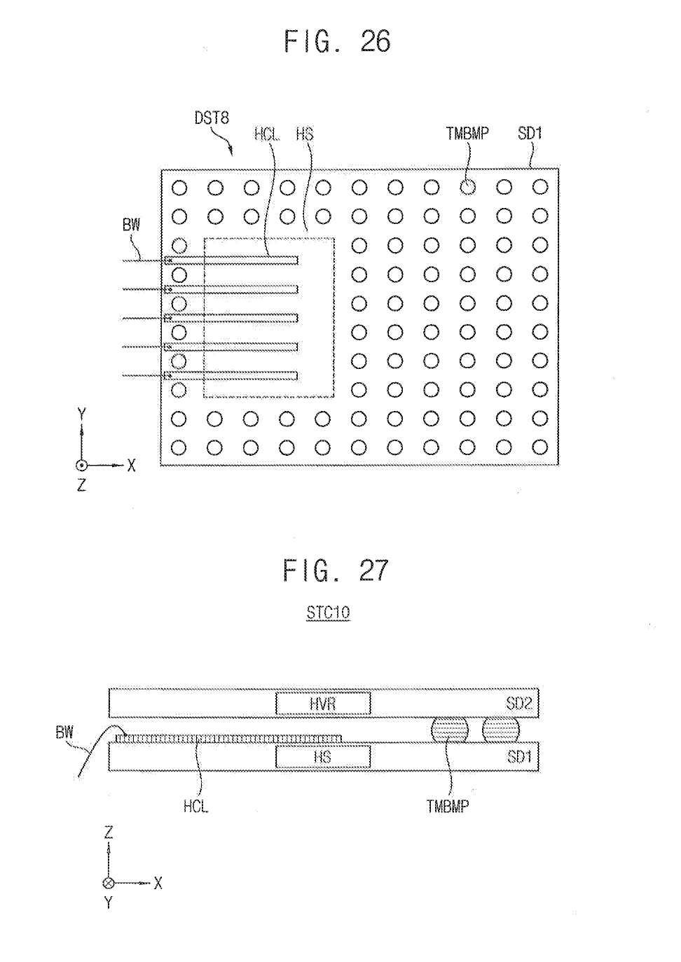

FIG. 26 is a diagram illustrating a disposition DST8 of thermal-mechanical bumps in a stacked semiconductor device according to an exemplary embodiment of the inventive concept, and FIG. 27 is a cross-sectional view illustrating a structure of the semiconductor device including the thermal-mechanical bump TMBMP of FIG. 26 according to an exemplary embodiment of the inventive concept.

Referring to FIGS. 26 and 27, a stacked semiconductor device STC10 may include a first semiconductor die SD1 including a heat source HS and a second semiconductor die SD2 including a heat-vulnerable region HVR, which is stacked on the first semiconductor die SD1. FIG. 25 illustrates two semiconductor dies for convenience of illustration but the number of the stacked semiconductor dies may be changed variously.

In an exemplary embodiment of the inventive concept, a heat conduction line HCL may be formed on a top surface or a bottom surface of the semiconductor die SD1 including the heat source HS such that a first end of the heat conduction line HCL contacts a portion near the heat source HS and a second end of the heat conduction line HCL is far from the heat source HS. The thermal-mechanical bump TMBMP may be removed from the first end of the heat conduction line HCL and a bonding wire BW may be disposed at the second end of the heat conduction line HCL.

For example, as illustrated in FIGS. 26 and 27, when the first semiconductor die SD1 includes the heat source HS and the second semiconductor die SD2 includes the heat-vulnerable regions HVR, the heat conduction lines HCL may be formed on the top surface of the first semiconductor die SD1. The heat transfer from the heat source HS to the heat-vulnerable region HVR may be decreased by removing the thermal-mechanical bump TMBMP from the first end of the heat conduction line HCL near the heat source HS and disposing the bonding wire BW on the second end of the heat conduction line HCL. The bonding wire BW may be connected to a heat spreader, a board on which the stacked semiconductor device STC10 is mounted, etc.

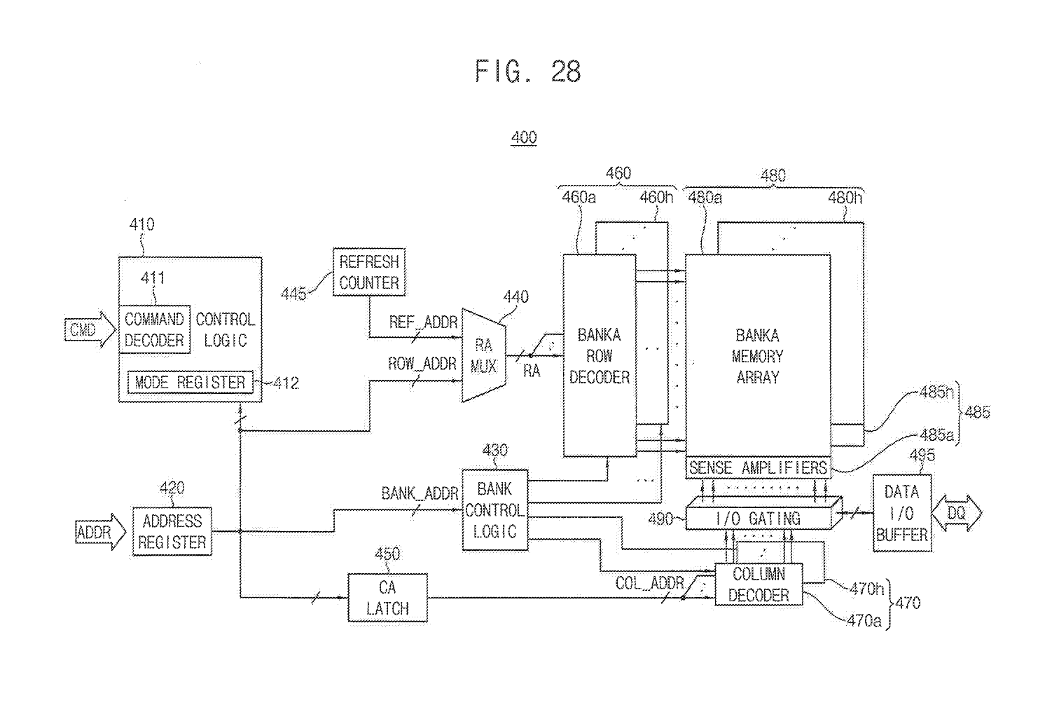

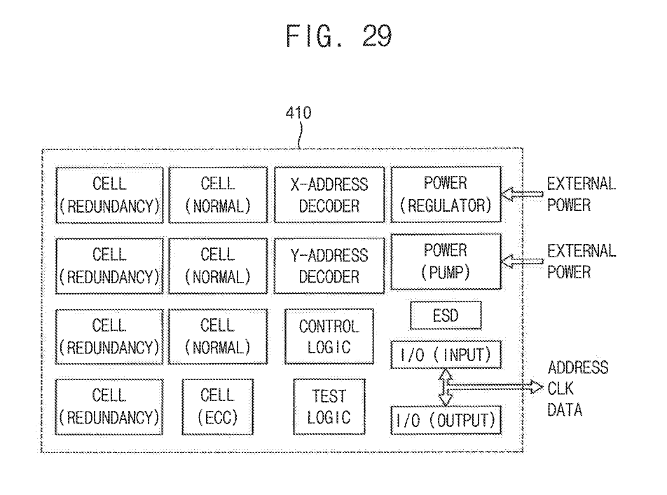

FIGS. 28 and 29 are block diagrams illustrating a semiconductor memory device according to an exemplary embodiment of the inventive concept.

Referring to 28, a memory device 400 may include a control logic 410, an address register 420, a bank control logic 430, a row address multiplexer 440, a column address latch 450, a row decoder 460, a column decoder 470, a memory cell array 480, a sense amplifier unit 485, an input/output (I/O) gating circuit 490, a data input/output (I/O) buffer 495 and a refresh counter 445.

The memory cell array 480 may include a plurality of bank arrays 480a˜480h. The row decoder 460 may include a plurality of bank row decoders 460a˜460h respectively coupled to the bank arrays 480a˜480h, the column decoder 470 may include a plurality of bank column decoders 470a˜470h respectively coupled to the bank arrays 480a˜480h, and the sense amplifier unit 485 may include a plurality of bank sense amplifiers 485a˜485h respectively coupled to the bank arrays 480a˜480h.

The address register 420 may receive an address ADDR including a bank address BANK_ADDR, a row address ROW_ADDR and a column address COL_ADDR from a memory controller. The address register 420 may provide the received bank address BANK_ADDR to the bank control logic 430, may provide the received row address ROW_ADDR to the row address multiplexer 440, and may provide the received column address COL_ADDR to the column address latch 450.

The bank control logic 430 may generate bank control signals in response to the bank address BANK_ADDR. One of the bank row decoders 460a˜460h corresponding to the bank address BANK_ADDR may be activated in response to the bank control signals, and one of the bank column decoders 470a˜470h corresponding to the bank address BANK_ADDR may be activated in response to the bank control signals.

The row address multiplexer 440 may receive the row address ROW_ADDR from the address register 420, and may receive a refresh row address REF_ADDR from the refresh counter 445. The row address multiplexer 440 may selectively output the row address ROW_ADDR or the refresh row address REF_ADDR as a row address RA. The row address RA that is output from the row address multiplexer 440 may be applied to the first through eighth bank row decoders 460a˜460h.

The activated one of the bank row decoders 460a˜460h may decode the row address RA that is output from the row address multiplexer 440, and may activate a word-line corresponding to the row address RA. For example, the activated bank row decoder may apply a word-line driving voltage to the word-line corresponding to the row address RA.

The column address latch 450 may receive the column address COL_ADDR from the address register 420, and may temporarily store the received column address COL_ADDR. In an exemplary embodiment of the inventive concept, in a burst mode, the column address latch 450 may generate column addresses that increment from the received column address COL_ADDR. The column address latch 450 may apply the temporarily stored or generated column address to the bank column decoders 470a˜470h.

The activated one of the bank column decoders 470a˜470h may decode the column address COL_ADDR that is output from the column address latch 450, and may control the input/output gating circuit 490 to output data corresponding to the column address COL_ADDR.

The I/O gating circuit 490 may include a circuitry for gating input/output data. The I/O gating circuit 490 may further include read data latches for storing data that is output from the bank arrays 480a˜480h, and write drivers for writing data to the bank arrays 480a˜480h.

Data to be read from one bank array of the bank arrays 480a˜480h may be sensed by a sense amplifier coupled to the one bank array from which the data is to be read, and may be stored in the read data latches. The data stored in the read data latches may be provided to the memory controller via the data I/O buffer 495. Data DQ to be written in one bank array of the bank arrays 480a˜480h may be provided to the data I/O buffer 495 from the memory controller. The write driver may write the data DQ in one bank array of the first through eighth bank arrays 480a˜480h.

The control logic 410 may control operations of the memory device 400. For example, the control logic 410 may generate control signals for the memory device 400 to perform a write operation or a read operation. The control logic 410 may include a command decoder 411 that decodes a command CMD received from the memory controller via a buffer chip and a mode register set 412 that sets an operation mode of the memory device 400.

FIG. 29 illustrates a configuration in which the components of the semiconductor memory device 400 of FIG. 28 are blocked according to their functions. As illustrated in FIG. 29, the function blocks may include memory core blocks CELL (REDUNDANCY), CELL (NORMAL) and CELL (ECC) including memory cells for storing data, address decoder blocks X-ADDRESS DECODER and Y-ADDRESS DECODER, a control logic block for controlling the memory core blocks, power blocks POWER (REGULATOR) and POWER (PUMP) for providing external power to the system, input-output blocks I/O (INPUT) and I/O (OUTPUT) for transferring an address signal ADDRESS, a clock signal CLK and a data signal DATA, a test logic block for testing the system, an electrostatic discharge protection block ESD, etc. Herein, ECC may stand for error correcting code.

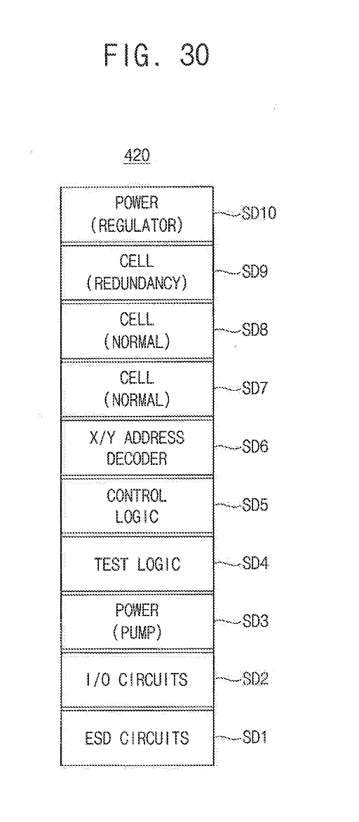

FIG. 30 is a diagram illustrating a stacked semiconductor device according to an exemplary embodiment of the inventive concept.

Referring to FIG. 30, a stacked semiconductor device 420 may include a plurality of semiconductor dies SD1 through SD10 that are stacked in a vertical direction. The function blocks as illustrated in FIG. 29 may be integrated in the respective semiconductor dies SD1 through SD10 as illustrated in FIG. 30, and such heterogeneous semiconductor dies may be stacked.

In a general technique, the components of the system may be mounted on a board in a package level, or all of the components may be integrated in a single semiconductor die to form a system on chip (SOC). In a system formed with multiple packages, the size of the system may be increased and the signal paths may be lengthened. This, however, may degrade power efficiency and performance of the system. In addition, the SOC has a limit in chip size and high manufacturing cost. In an exemplary embodiment of the inventive concept, the components of the system may be integrated and distributed in the independent semiconductor dies and then the semiconductor dies may be stacked to form the system as illustrated in FIG. 30.

In implementing the three-dimensional stack structure of FIG. 30, the individual components of the circuits integrated in the semiconductor dies may be connected with the through-substrate vias and the bumps. As described with reference to FIGS. 1 through 27, the stacked semiconductor device and the method of manufacturing the stacked semiconductor device according to exemplary embodiments of the inventive concept may efficiently dissipate an excess amount of heat from a heat source by changing the disposition or the structure of the thermal-mechanical bumps in view of the location of the heat source. Accordingly, the thermal characteristics of the devices may be optimized by dissipating excess heat, and thus, performance and productivity of the stacked semiconductor device may be increased.

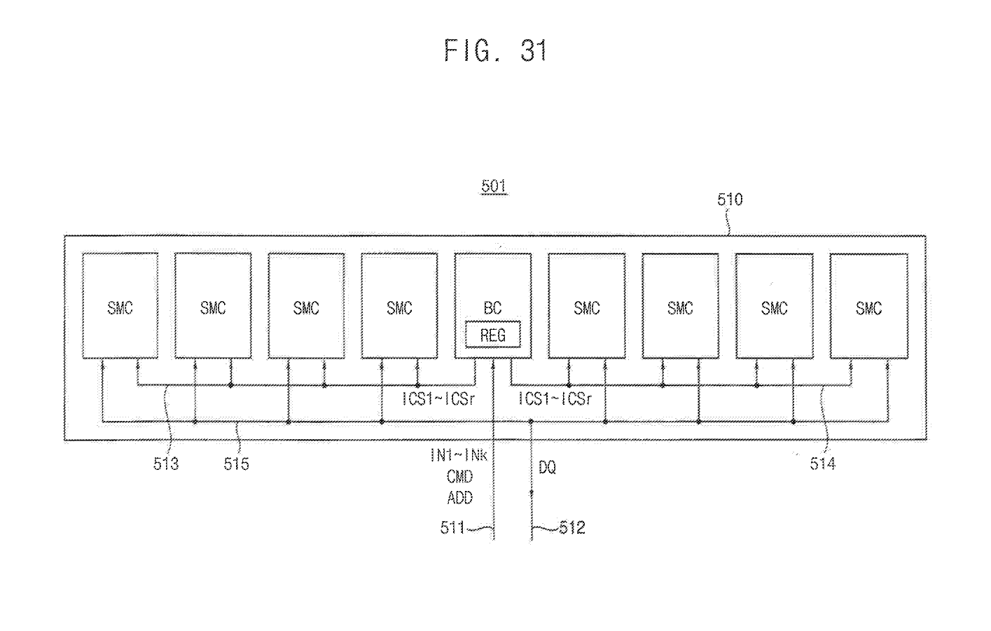

FIG. 31 is a block diagram illustrating a memory module according to an exemplary embodiment of the inventive concept.

Referring to FIG. 31, a memory module 501 may include a module substrate 510, a plurality of stacked semiconductor memory chips SMC and a buffer chip BC.

The stacked semiconductor memory chips SMC may be mounted on the module substrate 510 and each of the stacked semiconductor memory chips SMC may include a plurality of semiconductor dies stacked vertically. As described with reference to FIGS. 1 through 27, each of the stacked semiconductor memory chips SMC may efficiently dissipate an excessive amount of heat from a heat source by changing the disposition or the structure of thermal-mechanical bumps in view of the location of the heat source. The thermal characteristics of the chips may be optimized through the dissipation of the excessive amount of heat, and, thus performance and productivity of the stacked semiconductor device may be increased.

The stacked semiconductor memory chips SMC may receive data DQ from an external device such as a memory controller through data buses 512 and 515 in a write mode, or transmit the data DQ to the external device through the data buses 512 and 515 in a read mode.

The buffer chip BC may be mounted on the module substrate 510 and the buffer chip BC may receive command signals CMD, address signals ADD and control signals IN1˜INk through a control bus 511 to provide internal signals ICS1˜ICSr to the stacked semiconductor memory chips SMC through internal buses 513 and 514. The buffer chip BC may include a register REG to store control information of the memory module 501.

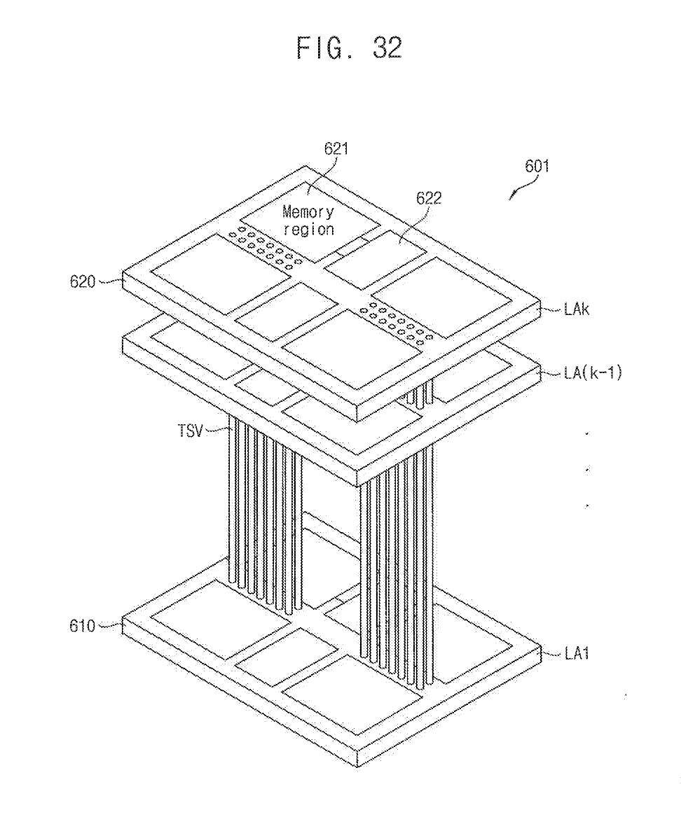

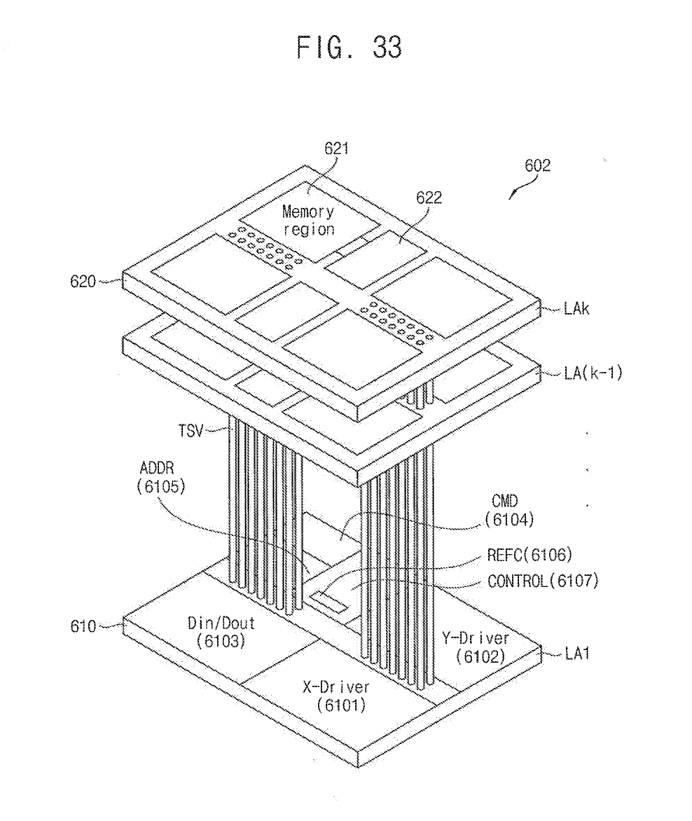

FIGS. 32 and 33 are diagrams illustrating structures of a stacked memory device according to exemplary embodiments of the inventive concept.

Referring to FIG. 32, a stacked semiconductor memory device 601 may include first through kth semiconductor integrated circuit layers LA1 through LAk, in which the first semiconductor integrated circuit layer LA1 may be a master layer and the other semiconductor integrated circuit layers LA2 through LAk may be slave layers.

The first through kth semiconductor integrated circuit layers LA1 through LAk may transmit and receive signals between the layers by through-substrate vias (e.g., through-silicon vias) TSVs. The first semiconductor integrated circuit layer LA1 as the master layer may communicate with an external device (e.g., a memory controller) through a conductive structure formed on an external surface. A description will be made regarding a structure and an operation of the stacked semiconductor memory device 601 by mainly referring to the first semiconductor integrated circuit layer LA1 or 610 as the master layer and the kth semiconductor integrated circuit layer LAk or 620 as the slave layer.

The first semiconductor integrated circuit layer 610 and the kth semiconductor integrated circuit layer 620 may include memory regions 621 and various peripheral circuits 622 for driving the memory regions 621. For example, the peripheral circuits may include a row (X)-driver for driving wordlines of the memory regions 621, a column (Y)-driver for driving bit lines of the memory regions 621, a data input/output unit (Din/Dout) for controlling input/output of data, a command buffer (CMD) for receiving a command CMD from outside and buffering the command CMD, and an address buffer (ADDR) for receiving an address from outside and buffering the address.

The stacked semiconductor memory device 601 may, as described with reference to FIGS. 1 through 27, efficiently dissipate an excessive amount of heat from a heat source by changing the disposition or the structure of thermal-mechanical bumps in view of the location of the heat source. The thermal characteristics of the device may be optimized through the dissipation of the excessive amount of heat, and thus, performance and productivity of the stacked semiconductor device may be increased.

Referring to FIG. 33, a stacked semiconductor memory device 602 may include first through kth semiconductor integrated circuit layers LA1 through LAk, in which the first semiconductor integrated circuit layer LA1 may be an interface layer and the other semiconductor integrated circuit layers LA2 through LAk may be memory layers.

The first through kth semiconductor integrated circuit layers LA1 through LAk may transmit and receive signals between the layers by through-substrate vias (e.g., through-silicon vias) TSVs. The first semiconductor integrated circuit layer LA1 as the interface layer may communicate with an external memory controller through a conductive structure formed on an external surface. A description will be made regarding a structure and an operation of the stacked semiconductor memory device 602 by mainly using the first semiconductor integrated circuit layer LA1 or 610 as the interface layer and the kth semiconductor integrated circuit layer LAk or 620 as the memory layer.

The first semiconductor integrated circuit layer 610 as the master layer may include various peripheral circuits for driving the memory regions 621 in the kth semiconductor integrated circuit layer 620 as the memory layer. For example, the first semiconductor integrated circuit layer 610 may include a row (X)-driver 6101 for driving wordlines of the memory regions 621, a column (Y)-driver 6102 for driving bit lines of the memory regions 621, a data input/output circuit (Din/Dout) 6103 for controlling the input/output of data, a command buffer (CMD buffer) 6104 for receiving a command CMD from the outside and buffering the command CMD, an address buffer (ADDR buffer) 6105 for receiving an address from the outside and buffering the address and a refresh controller (REFC) 6106.

The first semiconductor integrated circuit layer 610 may further include a control circuit 6107 and the control circuit 6107 may generate control signals to control the memory regions 621 in the kth semiconductor integrated circuit layer 620 based on the command-address signals provided from the memory controller.

The stacked semiconductor memory device 602 may, as described with reference to FIGS. 1 through 27, efficiently dissipate an excessive amount of heat from a heat source by changing the disposition or the structure of thermal-mechanical bumps based on the location of the heat source. The thermal characteristics of the stacked semiconductor memory device 602 may be optimized by the dissipation of the excessive amount of heat, and thus, performance and productivity of the stacked semiconductor device may be increased.

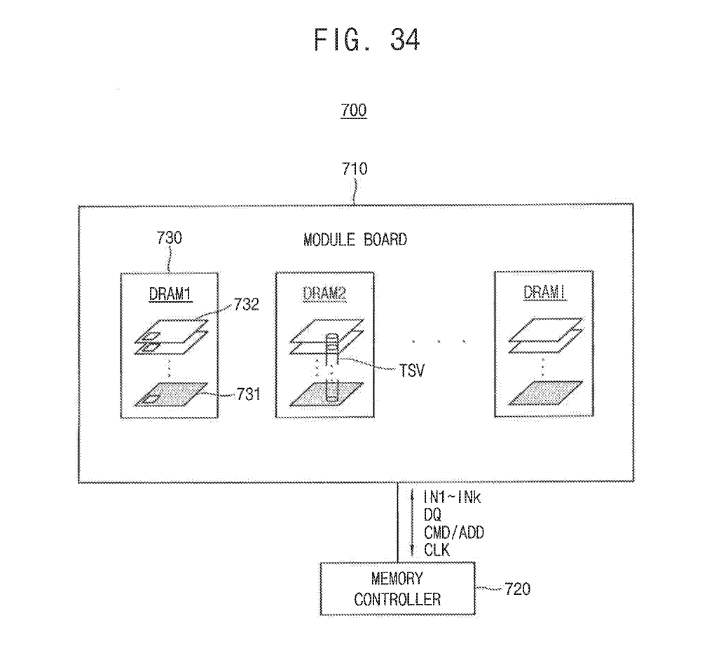

FIG. 34 is a block diagram illustrating a memory system according to an exemplary embodiment of the inventive concept.

Referring to FIG. 34, a memory system 700 may include a memory module 710 and a memory controller 720. The memory module 710 may include at least one semiconductor memory device 730 mounted on a module substrate. For example, the semiconductor memory device 730 may be a dynamic random access memory (DRAM) chip. In addition, the semiconductor memory device 730 may include a stack of semiconductor dies. In an exemplary embodiment of the inventive concept, the semiconductor dies may include a master die 731 and a slave dies 732, which may correspond to those as described with reference to FIG. 32. In an exemplary embodiment of the inventive concept, the semiconductor dies may include the interface die 731 and the memory dies or the slave dies 732, which may correspond to those as described with reference to FIG. 33. Signal transfer between the semiconductor chips may occur via through-substrate vias (e.g., through-silicon vias) TSVs.

The memory module 710 may communicate with the memory controller 720 via a system bus. Data DQ, command/address CMD/ADD, a clock signal CLK and control signals IN1˜INk may be transmitted and received between the memory module 710 and the memory controller 720 via the system bus.

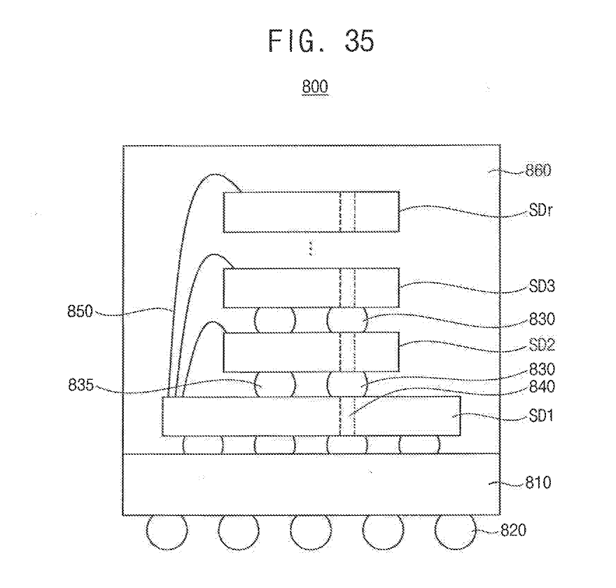

FIG. 35 is a diagram for describing a package structure of a memory chip according to an exemplary embodiment of the inventive concept.

Referring to FIG. 35, a stacked memory chip 800 may include a base substrate 810 and a plurality of semiconductor dies SD1˜SDr stacked on the base substrate 810.

The base substrate 810 may be a printed circuit board (PCB). External connecting members 820, e.g., package terminals comprised of conductive bumps, may be formed on a lower surface of the base substrate 810. Internal connecting members 830, e.g., chip terminals comprised of conductive bumps, may be formed on a upper surface of the base substrate 810 and between the semiconductor dies SD1˜SDr. In an exemplary embodiment of the inventive concept, the semiconductor dies SD1˜SDr may be connected to each other and to the base substrate 810 by through-substrate vias TSVs 840 and the conductive bumps. In an exemplary embodiment of the inventive concept, the semiconductor dies SD1˜SDr may be connected to the base substrate 810 by bonding wires 850 and the conductive bumps. In an exemplary embodiment of the inventive concept, the semiconductor dies SD1˜SDr may be connected to the base substrate 810 by a combination of the through-substrate vias 840, the conductive bumps, and the bonding wires 850. The stacked semiconductor dies SD1˜SDr may be packaged using the sealing member 860.

According to an exemplary embodiment of the inventive concept, thermal-mechanical bumps 835 not use in the transfer of the electrical signals may be disposed between the semiconductor dies SD1˜SDr. As described with reference to FIGS. 1 through 27, an excessive amount of heat from a heat source may be dissipated efficiently by changing the disposition or the structure of the thermal-mechanical bumps in view of the location of the heat source. The thermal characteristics of the stacked memory chip 800 may be optimized through the dissipation of the excessive amount of heat, and thus, performance and productivity of the stacked semiconductor device may be increased.

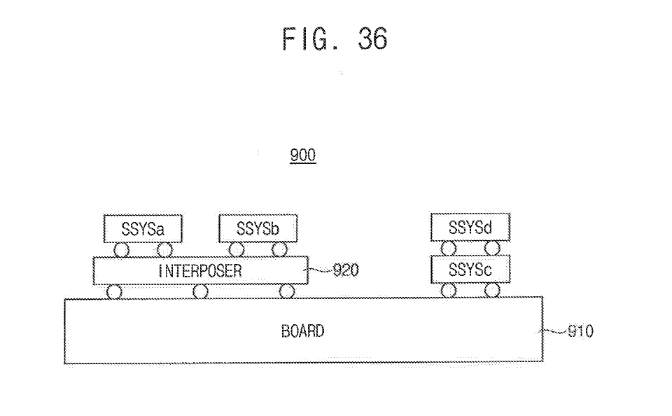

FIG. 36 is a diagram illustrating a system according to an exemplary embodiment of the inventive concept.

Referring to FIG. 36, a system 900 includes a board 910 and a plurality of subsystems SSYSa, SSYSb, SSYSc and SSYSd that are mounted on the board 910.

For example, the first subsystem SSYSa and the second subsystem SSYSb may be mounted on an interposer 920 that is mounted on the board 910, and the first subsystem SSYSa and the second subsystem SSYSb may be connected through signal lines or signal paths that are formed at the interposer 920. For example, the fourth subsystem SSYSd may be stacked on the third subsystem SSYSc to form a structure of a package on package (PoP). The interposer 920 and the PoP may be connected through signal bus lines that are formed at the board 910.

At least one of the subsystems SSYSa, SSYSb, SSYSc and SSYSd may be a stacked semiconductor device in which a plurality of semiconductor dies are stacked. As described with reference to FIGS. 1 through 27, an excessive amount of heat from a heat source may be dissipated efficiently by changing the disposition or the structure of thermal-mechanical bumps in view of the location of the heat source. The thermal characteristics of the system 900 may be optimized through the dissipation of the excessive amount of heat, and thus, performance and productivity of the stacked semiconductor device may be increased.

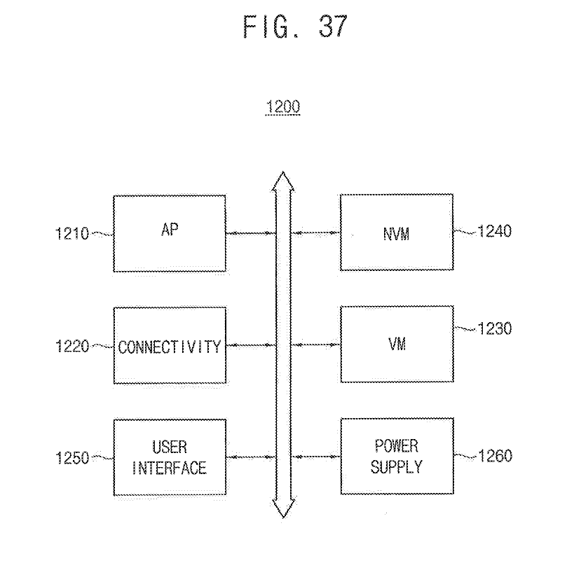

FIG. 37 is a block diagram illustrating a mobile system according to an exemplary embodiment of the inventive concept.

Referring to FIG. 37, a mobile system 1200 includes an application processor (AP) 1210, a connectivity unit 1220, a volatile memory device (VM) 1230, a nonvolatile memory device (NVM) 1240, a user interface 1250, and a power supply 1260. In an exemplary embodiment of the inventive concept, the mobile system 1200 may be, for example, a mobile phone, a smart phone, a personal digital assistant (PDA), a portable multimedia player (PMP), a digital camera, a music player, a portable game console, a navigation system, or another type of electronic device.

The application processor 1210 may execute applications such as a web browser, a game application, a video player, etc. In an exemplary embodiment of the inventive concept, the application processor 1210 may include a single core or multiple cores. For example, the application processor 1210 may be a multi-core processor such as a dual-core processor, a quad-core processor, a hexa-core processor, etc. The application processor 1210 may include an internal or external cache memory.

The connectivity unit 1220 may perform wired or wireless communication with an external device. For example, the connectivity unit 1220 may perform Ethernet communication, near field communication (NFC), radio frequency identification (RFID) communication, mobile telecommunication, memory card communication, universal serial bus (USB) communication, etc. In an exemplary embodiment of the inventive concept, the connectivity unit 1220 may include a baseband chipset that supports communications, such as global system for mobile communications (GSM), general packet radio service (GPRS), wideband code division multiple access (WCDMA), high speed downlink/uplink packet access (HSxPA), etc.

The volatile memory device 1230 may store data processed by the application processor 1210, or may operate as a working memory. For example, the volatile memory device 1230 may be a DRAM, such as double data rate (DDR) synchronous DRAM (SDRAM), low power DDR (LPDDR) SDRAM, graphics DDR (GDDR) SDRAM, rambus DRAM (RDRAM), etc.

The nonvolatile memory device 1240 may store a boot image for booting the mobile system 1200. For example, the nonvolatile memory device 1240 may be an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), etc.

The user interface 1250 may include at least one input device, such as a keypad, a touch screen, etc., and at least one output device, such as a speaker, a display device, etc. The power supply 1260 may supply a power supply voltage to the mobile system 1200. In an exemplary embodiment of the inventive concept, the mobile system 1200 may further include a camera image processor, a CMOS image sensor (CIS), and/or a storage device, such as a memory card, a solid state drive (SSD), a hard disk drive (HDD), a compact disk read only memory (CD-ROM), etc.

In an exemplary embodiment of the inventive concept, the mobile system 1200 and/or components of the mobile system 1200 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline integrated circuit (SOIC), shrink small outline package (SSOP), thin small outline package (TSOP), system in package (SIP), multi-chip package (MCP), wafer-level fabricated package (WFP), wafer-level processed stack package (WSP), etc.

At least one of the application processor 1210, the connectivity unit 1220, the volatile memory device 1230, the nonvolatile memory device 1240 and the user interface 1250 may be a stacked semiconductor device in which a plurality of semiconductor dies are stacked. As described with reference to FIGS. 1 through 27, an excessive amount of heat from a heat source may be dissipated efficiently by changing the disposition or the structure of thermal-mechanical bumps in view of the location of the heat source. The thermal characteristics of the mobile system 1200 may be optimized by the dissipation of the excessive amount of heat, and thus, performance and productivity of the stacked semiconductor device may be increased.

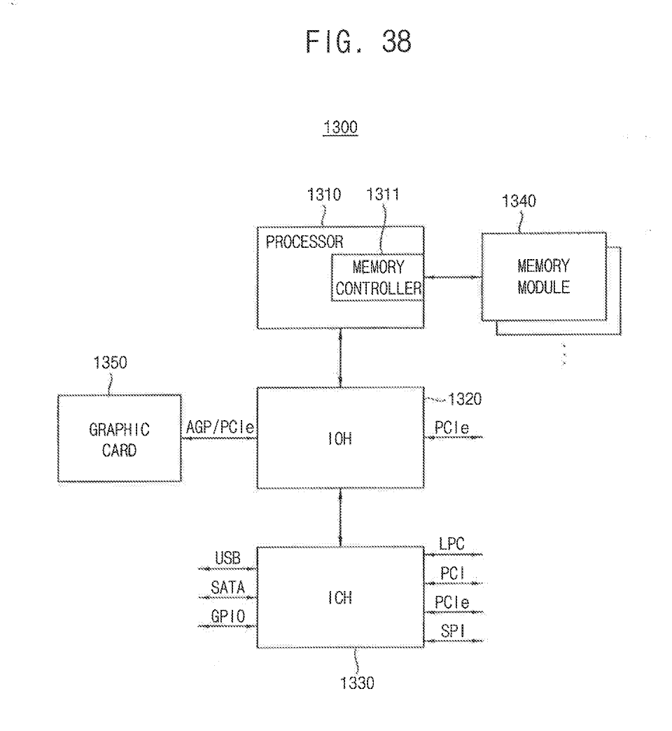

FIG. 38 is a block diagram illustrating a computing system according to an exemplary embodiment of the inventive concept.

Referring to FIG. 38, a computing system 1300 includes a processor 1310, an input/output hub (IOH) 1320, an input/output controller hub (ICH) 1330, at least one memory module 1340, and a graphics card 1350. In an exemplary embodiment of the inventive concept, the computing system 1300 may be a personal computer (PC), a server computer, a workstation, a laptop computer, a mobile phone, a smart phone, a personal digital assistant (PDA), a portable multimedia player (PMP), a digital camera, a digital television, a set-top box, a music player, a portable game console, a navigation system, etc.

The processor 1310 may perform various computing functions such as executing specific software for performing specific calculations or tasks. For example, the processor 1310 may be a microprocessor, a central processing unit (CPU), a digital signal processor, or the like. In an exemplary embodiment of the inventive concept, the processor 1310 may include a single core or multiple cores. For example, the processor 1310 may be a multi-core processor, such as a dual-core processor, a quad-core processor, a hexa-core processor, etc. Although FIG. 38 illustrates the computing system 1300 including one processor 1310, in an exemplary embodiment of the inventive concept, the computing system 1300 may include a plurality of processors. The processor 1310 may include an internal or external cache memory.

The processor 1310 may include a memory controller 1311 for controlling operations of the memory module 1340. The memory controller 1311 included in the processor 1310 may be referred to as an integrated memory controller (IMC). A memory interface between the memory controller 1311 and the memory module 1340 may be implemented with a single channel including a plurality of signal lines, or may be implemented with multiple channels, to each of which at least one memory module 1340 may be coupled. In an exemplary embodiment of the inventive concept, the memory controller 1311 may be located inside the input/output hub 1320, which may be referred to as memory controller hub (MCH).

The memory module 1340 may include a plurality of memory devices that store data provided from the memory controller 1311. At least one of the memory devices may be a stacked semiconductor device in which a plurality of semiconductor dies are stacked. As described with reference to FIGS. 1 through 27, an excessive amount of heat from a heat source may be dissipated efficiently by changing the disposition or the structure of thermal-mechanical bumps in view of the location of the heat source. The thermal characteristics of the computing system 1300 may be optimized by the dissipation of the excessive amount of heat, and thus, performance and productivity of the stacked semiconductor device may be increased.

The input/output hub 1320 may manage data transfer between the processor 1310 and other devices, such as the graphics card 1350. The input/output hub 1320 may be coupled to the processor 1310 via various interfaces. For example, the interface between the processor 1310 and the input/output hub 1320 may be a front side bus (FSB), a system bus, a HyperTransport, a lightning data transport (LDT), a QuickPath interconnect (QPI), a common system interface (CSI), etc. Although FIG. 38 illustrates the computing system 1300 including one input/output hub 1320, in an exemplary embodiment of the inventive concept, the computing system 1300 may include a plurality of input/output hubs. The input/output hub 1320 may provide various interfaces with other devices. For example, the input/output hub 1320 may provide an accelerated graphics port (AGP) interface, a peripheral component interface-express (PCIe), a communications streaming architecture (CSA) interface, etc.

The graphics card 1350 may be coupled to the input/output hub 1320 via AGP or PCIe. The graphics card 1350 may control a display device for displaying an image. The graphics card 1350 may include an internal processor for processing image data and an internal memory device. In an exemplary embodiment of the inventive concept, the input/output hub 1320 may include an internal graphics device along with or instead of the graphics card 1350 outside the graphics card 1350. The graphics device included in the input/output hub 1320 may be referred to as integrated graphics. Further, the input/output hub 1320 including the internal memory controller and the internal graphics device may be referred to as a graphics and memory controller hub (GMCH).

The input/output controller hub 1330 may perform data buffering and interface arbitration to efficiently operate various system interfaces. The input/output controller hub 1330 may be coupled to the input/output hub 1320 via an internal bus, such as a direct media interface (DMI), a hub interface, an enterprise Southbridge interface (ESI), PCIe, etc. The input/output controller hub 1330 may provide various interfaces with peripheral devices. For example, the input/output controller hub 1330 may provide a universal serial bus (USB) port, a serial advanced technology attachment (SATA) port, a general purpose input/output (GPIO), a low pin count (LPC) bus, a serial peripheral interface (SPI), PCI, PCIe, etc.

In an exemplary embodiment of the inventive concept, the processor 1310, the input/output hub 1320 and the input/output controller hub 1330 may be implemented as separate chipsets or separate integrated units. In an exemplary embodiment of the inventive concept, at least two of the processor 1310, the input/output hub 1320 and the input/output controller hub 1330 may be implemented as a single chipset. In addition, while many features of the exemplary embodiments are disclosed as units, in other embodiments those features may be implemented as other forms of logic including but not limited to code-based operations performed by a processor.

As described above, a stacked semiconductor device and a method of manufacturing the stacked semiconductor device according to exemplary embodiments of the inventive concept may efficiently dissipate an excessive amount of heat from a heat source by changing the disposition or the structure of thermal-mechanical bumps in view of the location of the heat source. The thermal characteristics of the stacked semiconductor device may be optimized by the dissipation of the excessive amount of heat, and thus, performance and productivity of the stacked semiconductor device may be increased.

Exemplary embodiments of the inventive concept may be applied to various devices and systems. For example, the inventive concept may be applied to systems such as a mobile phone, a smart phone, a personal digital assistant (PDA), a portable multimedia player (PMP), a digital camera, a camcorder, personal computer (PC), a server computer, a workstation, a laptop computer, a digital TV, a set-top box, a portable game console, a navigation system, etc.

While the inventive concept has been particularly shown and described with reference to exemplary embodiments thereof, it will be apparent to those of ordinary skill in the art that various changes in form and detail may be made therein without departing from the spirit and scope of the inventive concept as defined by the following claims.

1. A stacked semiconductor device, comprising:
a plurality of semiconductor dies stacked in a vertical direction; and
a plurality of thermal-mechanical bumps disposed in bump layers between the semiconductor dies,
wherein fewer thermal-mechanical bumps are disposed at a location near a heat source included in the semiconductor dies than at other locations, or a structure of the thermal-mechanical bumps at the location near the heat source is different from a structure of the thermal-mechanical bumps at other locations.

2. The stacked semiconductor device of claim 1, wherein the disposition or the structure of the thermal-mechanical bumps in a first bump layer is different from the disposition or the structure of the thermal-mechanical bumps in a second bump layer.

3. The stacked semiconductor device of claim 1, wherein the semiconductor dies include a first semiconductor die including the heat source and a second semiconductor die including a heat vulnerable region, and
wherein a number of the thermal-mechanical bumps in the bump layer between the first semiconductor die and the second semiconductor die is smaller than a number of the thermal-mechanical bumps in the other bump layers.

4. The stacked semiconductor device of claim 1, wherein the semiconductor dies include a first semiconductor die including the heat source and a second semiconductor die including a heat vulnerable region, and
wherein a thermal conductivity of the thermal-mechanical bumps in the bump layer between the first semiconductor die and the second semiconductor die is lower than a thermal conductivity of the thermal-mechanical bumps in the other bump layers.

5. The stacked semiconductor device of claim 1, wherein the semiconductor dies include a first semiconductor die including the heat source and a second semiconductor die including a heat vulnerable region and the second semiconductor die is adjacent to the first semiconductor die in an upward direction or in a downward direction, and
wherein a density of the thermal-mechanical bumps at an area near the heat source in the bump layer between the first semiconductor die and the second semiconductor die is lower than a density of the thermal-mechanical bumps at other areas in the bump layer between the first semiconductor die and the second semiconductor die.

6. The stacked semiconductor device of claim 1, wherein the semiconductor dies include a first semiconductor die including the heat source and a second semiconductor die including a heat vulnerable region and the second semiconductor die is adjacent to the first semiconductor die in an upward direction or in a downward direction, and
wherein a thermal conductivity of an area near the heat source in the bump layer between the first semiconductor die and the second semiconductor die is lower than a thermal conductivity of other areas in the bump layer between the first semiconductor die and the second semiconductor die.

7. The stacked semiconductor device of claim 1, further comprising:
a heat spreader disposed in above or below the semiconductor die including the heat source, and
wherein a density of the thermal-mechanical bumps at an area near the heat source in the bump layer between the heat spreader and the semiconductor die including the heat source is lower than a density of the thermal-mechanical bumps at other areas in the bump layer between the heat spreader and the semiconductor die including the heat source.

8. The stacked semiconductor device of claim 1, further comprising:
a heat-blocking layer that is formed on a top surface or a bottom surface of the semiconductor die including the heat source.

9. The stacked semiconductor device of claim 1, further comprising:
a heat conduction line that is formed on a top surface or a bottom surface of the semiconductor die including the heat source such that a first end of the heat conduction line contacts an area near the heat source and a second end of the heat conduction line does not contact the heat source.

10. The stacked semiconductor device of claim 9, wherein a thermal-mechanical bump is not located at the first end of the heat conduction line and a thermal-mechanical bump is disposed on the second end of the heat conduction line.

11. The stacked semiconductor device of claim 9, wherein a thermal-mechanical bump is not located at the first end of the heat conduction line and a bonding wire is disposed on the second end of the heat conduction line.

12. The stacked semiconductor device of claim 1, wherein the stacked semiconductor device is a memory device and a plurality of function blocks of the memory device are distributed and integrated in the semiconductor dies.

13. A method of manufacturing a stacked semiconductor device, comprising:
stacking a plurality of semiconductor dies in a vertical direction;
disposing a plurality of thermal-mechanical bumps in bump layers between the semiconductor dies; and
changing a location or a structure of the thermal-mechanical bumps in view of a location of a heat source included in the semiconductor dies.

14. The method of claim 13, wherein changing the location or the structure of the thermal-mechanical bumps includes:
decreasing a number of the thermal-mechanical bumps at a location closer the semiconductor die including the heat source or increasing a number of the thermal-mechanical bumps at a location farther from the semiconductor die including the heat source.

15. The method of claim 13, wherein changing the location or the structure of the thermal-mechanical bumps includes:
decreasing a thermal conductivity of the thermal-mechanical bumps at a location closer the semiconductor die including the heat source or increasing a thermal conductivity of the thermal-mechanical bumps at a location farther from the semiconductor die including the heat source.

16-23. (canceled)

24. A semiconductor device, comprising:
a first Semiconductor die disposed on a substrate;
a layer disposed on the first semiconductor die;
a second semiconductor die disposed on the substrate, wherein the first semiconductor die, the layer and the second semiconductor die are sequentially arranged in a direction perpendicular to an upper surface of the substrate;
a heat source disposed in the first semiconductor die;
a heat vulnerable region disposed in the second semiconductor die and near the heat source; and
a plurality of thermal-mechanical bumps disposed in the layer, wherein a number of the thermal-mechanical bumps near the heat source is less than that away from the heat source, or a characteristic of the thermal-mechanical bumps near the heat source is different from that of those away from the heat source.

25. The semiconductor device of claim 24, wherein the layer includes a plurality of signal bumps.

26. The semiconductor device of claim 25, wherein a signal bump transfers an electrical signal or a power between the first and second semiconductor dies, and a thermal-mechanical bump transfers heat between the first and second semiconductor dies.

27. The semiconductor device of claim 24, wherein the first and second semiconductor dies are identical or different.

28. The semiconductor device of claim 24, wherein a thermal conductivity of the thermal-mechanical bumps near the heat source is less than that of those away from the heat source.
